(19) United States
(12) Patent Application Publication
(10) Pub. No.: US 2026/0056462 A1
(43) Pub. Date: Feb. 26, 2026

(54) POSITIVE-TONE ORGANOMETALLIC EUV RESISTS

(71) Applicant: The Research Foundation for the State University of New York, Albany, NY (US)

(72) Inventors: Robert BRAINARD, Albany, NY (US); Jordan GREENOUGH, Albany, NY (US)

(21) Appl. No.: 19/104,670

(22) PCT Filed: Aug. 16, 2023
(86) PCT No.: PCT/US2023/030376

§ 371 Date: Feb. 18, 2025

Related U.S. Application Data
(60) Provisional application No. 63/398,311, filed on Aug. 16, 2022.

(51) Int. Cl. G03F 7/004; C07F 7/22; C07F 9/92; C07F 11/00

(52) U.S. Cl. CPC G03F 7/0042; C07F 7/2224; C07F 9/92; C07F 11/00

(57) ABSTRACT

Embodiments disclosed herein are directed to positive-tone photoresist compositions. Traditional chemically amplified resists have intrinsic limitations for use in high resolution Extreme UltraViolet (EUV) lithography due to low EUV absorptivity. Positive-tone photoresists efficiently absorb EUV light are needed to meet demands of high resolution, high sensitivity, and low line-edge-roughness. Organometallic complexes are promising candidates providing high EUV absorptivity. Positive-tone resists are used for most lithography steps in high-volume manufacturing making metal-containing positive-tone resists enormously valuable. Thus, embodiments herein disclose new positive-tone photoresist lithography compositions, and methods for forming resist patterns using one or more lithography compositions.

### CROSS-REFERENCE TO RELATED APPLICATIONS

The present disclosure claims priority or the benefit under 35 U.S.C. § 119 of U.S. provisional application No. 63/398,311 filed Aug. 16, 2022, herein entirely incorporated by reference.

### FIELD OF THE INVENTION

The present disclosure is generally in the fields of organometallic chemistry and electronic device manufacturing. More particularly, embodiments of the disclosure provide lithography compositions and methods of depositing films such as radiation sensitive films, which can be used for patterning applications with UV light, extreme ultra-violet (“EUV”) light or electron-beam radiation to form high resolution patterns with low line width roughness. Further embodiments of the disclosure are directed to compositions and methods for use in semiconductor manufacturing; specifically positive-tone organometallic photoresist compounds for use in extreme ultra-violet photolithography.

### BACKGROUND

In forming electronic devices such as semiconductor-based structures, materials are patterned to integrate a predetermined structure. Structures are typically formed through sequential deposition and etching steps through which a pattern is formed of the various materials. In this way, many devices such as transistors can be formed in a high-density area.

Organic compositions can be used as patterned photoresists (i.e., resists) such as radiation patterned resists, so that a pattern alters the chemical structure of the organic compositions corresponding with the pattern. For example, processes for the patterning of semiconductor wafers can include lithographic transfer of a desired image from a thin film of organic radiation-sensitive material. The patterning of the resist generally involves several process sequences including exposing the resist to an energy source, such as through a mask, to record a latent image and then developing and removing selected regions of the resist. For a positive-tone resist, the exposed regions are altered to make such regions selectively removable, while for a negative-tone resist, the unexposed regions are selectively removable.

Generally, the pattern is formed using radiation to alter a portion of the resist while the other portions of the resist act as a protective layer such as an etch-resistant layer. The substrate can be selectively etched through holes in the remaining areas of the protective resist layer. Alternatively, materials can be deposited into the exposed regions of the underlying substrate through the developed holes in the remaining areas of the protective resist layer. Ultimately, the protective resist layer is removed. Generally, the process can be repeated to form additional layers of patterned material. Additional processing sequences can be used, such as the deposition of conductive materials or implantation of dopants. In the fields of micro- and nanofabrication, feature sizes in integrated circuits have become very small to achieve high-integration densities and improve circuit function.

Traditional chemically amplified resists (CARs) have intrinsic limitations for use in high resolution Extreme UltraViolet (EUV) lithography due to low EUV absorptivity. A new generation of resists that efficiently absorb EUV light are needed to meet demands of high resolution, high sensitivity, and low line-edge-roughness. Organometallic complexes are promising candidates providing high EUV absorptivity. One challenge, however, is the exceeding scarcity of positive-tone organometallic resists. Currently, positive-tone resists are used for most lithography steps in high-volume manufacturing making metal-containing positive-tone resists enormously valuable.

Prior art-of-interest includes U.S. Pat. No. 10,228,618 entitled Organotin oxide hydroxide patterning compositions, precursors, and patterning (herein incorporated entirely by reference), however, the methods do not provide high resolution lithography patterning coatings based on the chemistry, compositions, and/or methods of the present disclosure.

Prior art-of-interest also includes U.S. Pat. No. 11,156,920 entitled Lithography composition, a method for forming resist patterns and a method for making semiconductor devices (herein incorporated entirely by reference), however, the disclosure does not provide the compositions of the present disclosure.

Accordingly, there is a continuing need in the art for new positive-tone photoresist lithography compositions, methods for forming resist patterns using one or more lithography compositions, and semiconductor device manufacturing methods using film and/or lithography compositions.

### SUMMARY OF THE INVENTION

In embodiments, the present disclosure provides new film compositions, lithography compositions, methods for forming resist patterns using a film or lithography composition, and other methods of using the film or lithography compositions as more fully disclosed herein below.

According to embodiments herein, new positive-tone lithographic compositions having the following formula, RₐL_{b}M_{c}B_{d}(QR′)ₑ are disclosed. According to an embodiment, the components of the aforementioned formula are M, which represents tellurium (Te), antimony (Sb), tin (Sn), Iodine (I) or bismuth (Bi); R, when present, is independently an aromatic or aliphatic hydrocarbon; L, when present, is independently a ligand comprising a heteroatom bound to M; B, when present, is a molecular fragment that is bound to two or more M atoms; Q is a molecular fragment comprising a heteroatom bound to M and a carbon, sulfur or phosphorus bound to a R′ group; R′ is an alkyl or aromatic fragment containing either an alkene or an alkyne; and a=0-12; b=0-12; c=1-12; d=0-12; and e=1-8.

According to an embodiment disclosed herein, the R of the positive-tone lithographic composition is independently an aromatic or aliphatic hydrocarbon selected from the group consisting of: —C₆H₅, —CH₃, —CH₂CH₃, —CH(CH₃)₂, —C(CH₃)₃, —CH═CH₂, —C(CH₃)=CH₂, —CH₂CH═CH₂, —CH₂C≡CH, —CH₂C=N, —CH₂C₆H₅, —C₆H₄CH═CH₂, —C₆H₄C(CH₃)=CH₂, —CH₂C₆H₄CH═CH₂, —C₆H₄OCH₃, p-C₆H₄OCH₃, —C₆H₄CH₂CH₃, —CH₂C₆H₄OCH₃, —C₆H₁₁, —CH₂C₁₀H₇, —CH₂C₆H₄C₆H₅, —CH(C₆H₅)₂, —CH₂C₆H₄C(CH₃)₃, —CH₂C₆H₄F, —CH₂C₆H₃F₂, —CH₂C₆H₂F₃, —CH₂C₆F₅, —CH(CH₃)C₆H₅, —CH(CH₃)C₁₀H₇, —CH(CH₃)C₆H₄C₆H₅, and —CH(CH₃)C₆H₄C(CH₃)₃.

According to an embodiment disclosed herein, the L of the positive-tone lithographic composition is independently a ligand selected from the group consisting of: —F, —Cl, —Br, —I, —OH₂, —OH, —OCH₃, —OCH(CH₃)₂, —OC(CH₃)₃, —NC₅H₅, —O(CH₂CH₃)₂, —P(CH₂CH₃)₃, —O(CH₂)₄, —SH₂, —SH, —SCH₃, —SCH(CH₃)₂, —SC(CH₃)₃, —S(CH₂CH₃)₂, —S(CH₂)₄, —CN, —O₂CR, or —C₂O₄.

According to an embodiment disclosed herein, the B of the positive-tone lithographic composition is selected from the group consisting of: —O—, —S—, —Te(O)₆—, —I(═O)O₅—, —C₂O₄—, —SO₄—, —PO₄—, —(CH₂)₂C₆H₄(CH₂)₂—, —OO—, —OCH₂O—, —OCH₂CH₂O—, —OCH₂CH₂CH₂O—, —OCH₂CH₂CH₂CH₂O—, —OC₆H₄O—, —OCH₂C₆H₄CH₂O—, —OCH₂CH═CHCH₂O—, —OCH₂C≡CCH₂O—, —SCH₂CH₂S—, —SCH₂CH₂CH₂S—, —SCH₂CH₂CH₂CH₂S—, —SC₆H₄S—, —SCH₂C₆H₄CH₂S—, —SCH₂CH═CHCH₂S—, —SCH₂C≡CCH₂S—, —O₂CCH₂CO₂—, —O₂CCH₂CH₂CO₂—, —O₂CCH₂C₆H₄CH₂CO₂—, —NHC═ONH—, —CH₂—, —CH(C₆H₅)—, —CH(CN)—, —CH₂CH₂—, —CH₂CH₂CH₂—, —CH₂CH₂CH₂CH₂—, —CH(CH₃)—, —CH(C₆H₅)—, —CH₂CH═CHCH₂—, —CH₂C≡CCH₂—, and —CH₂C₆H₄CH₂.

According to another embodiment disclosed herein, the Q of the positive-tone lithographic composition is selected from the group consisting of: —O₂C—, —O₃S—, —O₃P—, —O₂(HO)P—, —S(O═)C—, and —O₂C(O=C)—.

According to further embodiments disclosed herein, the QR′ of the positive-tone lithographic composition is selected from the group consisting of:

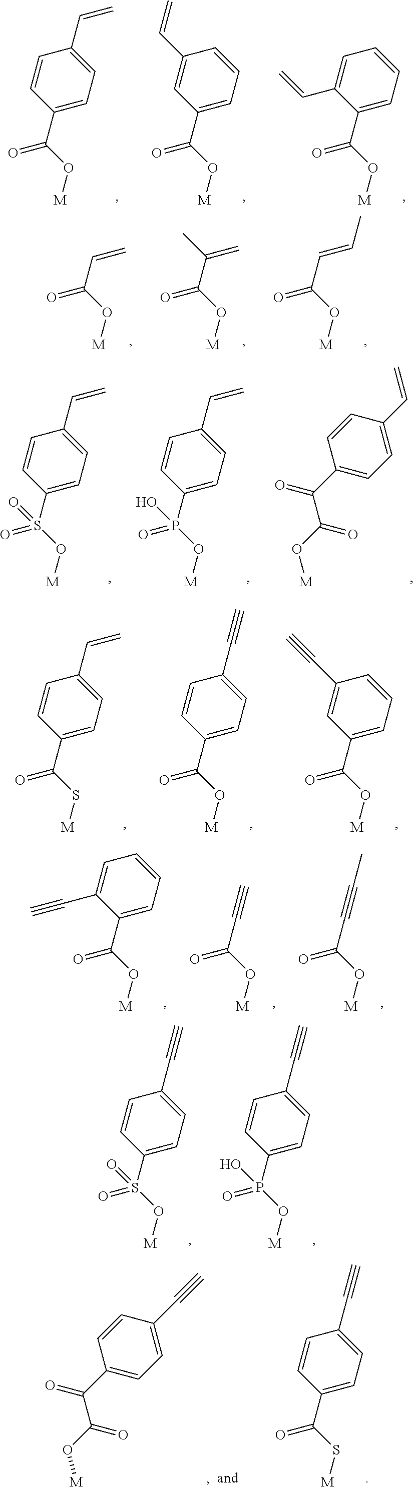

According to another embodiment disclosed herein, the QR′ of the positive-tone lithographic composition is (p-vinylbenzoate)₂ (SH-11) and M is Sb.

According to yet another embodiment disclosed herein, the positive-tone lithographic composition of the formula RₐL_{b}M_{c}B_{d}(QR′)ₑ comprises one of the following structural formula:

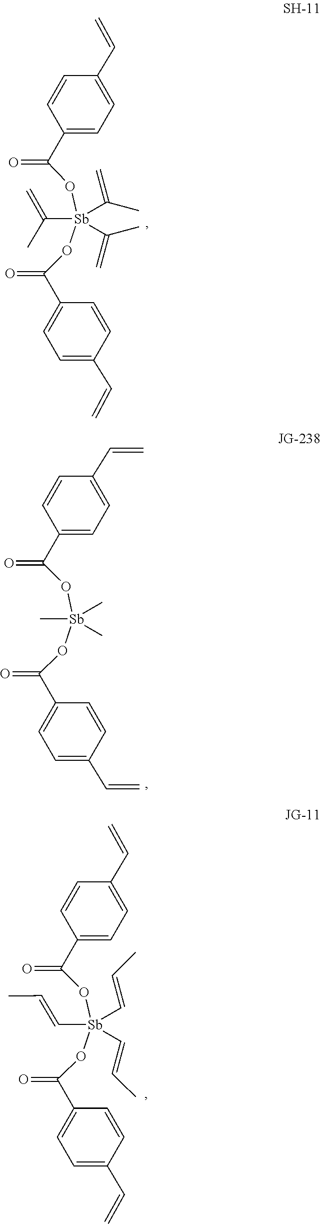

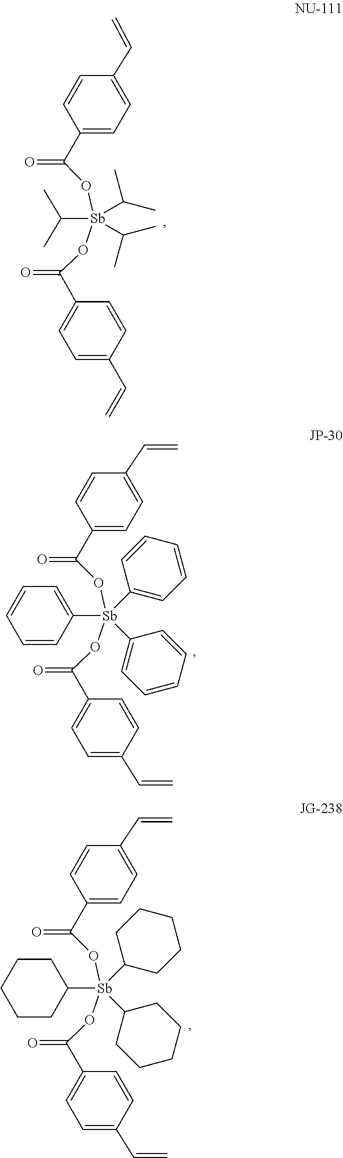

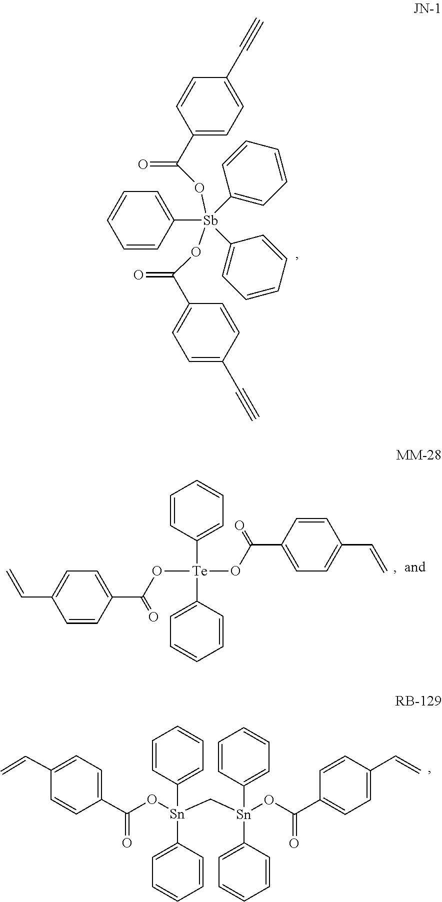

According to another embodiment disclosed herein, the positive-tone lithographic composition has following structural formula:

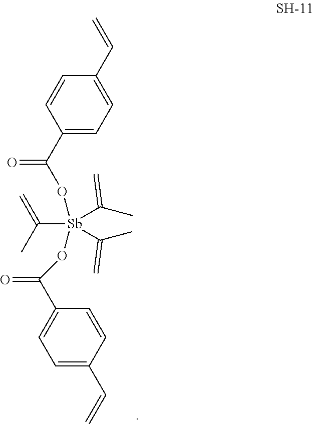

According to yet another embodiment disclosed herein, the positive-tone lithographic composition has following structural formula:

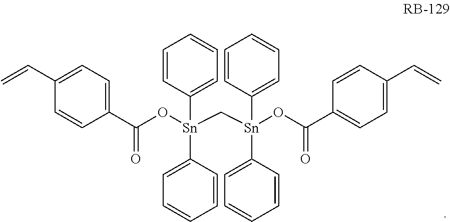 [SMILES: C=Cc1ccc(C(=O)[O][Sn]([CH2][Sn]([O]C(=O)c2ccc(C=C)cc2)([c]2ccccc2)[c]2ccccc2)([c]2ccccc2)[c]2ccccc2)cc1]

According to another embodiment disclosed herein, the positive-tone lithographic composition's solubility increases in an alkaline aqueous developer solution upon exposure to actinic radiation to provide positive-tone properties.

According to yet another embodiment disclosed herein, the positive-tone lithographic composition utilizes a developer that is 0.1-20% of an aqueous 0.26 M solution of tetramethylammonium hydroxide (TMAH). And according to another embodiment disclosed herein, the positive-tone lithographic composition utilizes a developer that is 1-10% of an aqueous 0.26 M of tetramethylammonium hydroxide (TMAH) solution. Other embodiments include coating solutions containing an organic solvent and a the positive-tone lithographic compositions disclosed herein. Additional embodiments include methods for forming a radiation patternable coating by contacting the disclosed coating solution with a substrate under conditions suitable for forming a film atop the substrate.

Other compositions, apparatus, methods, features, and advantages will be or become apparent to one with skill in the art upon examination of the following drawings and detailed description. It is intended that all such additional compositions, apparatus, methods, features and advantages be included within this description, be within the scope of the present disclosure, and be protected by the accompanying claims.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 presents three mononuclear photoresists of embodiments disclosed herein.

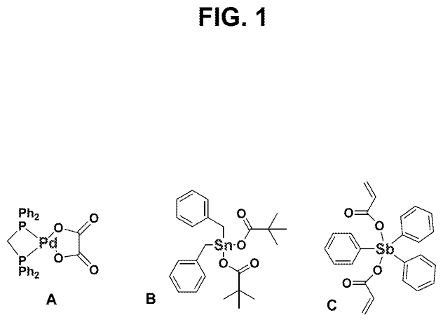

FIG. 2A presents olefin-containing carboxylate ligands, i.e., QR′ ligands and FIG. 2B presents alkyne-containing carboxylate ligands i.e. QR′ ligands, respectively, which are described in embodiments disclosed herein.

FIG. 3A presents the chemical structure of triisopropenylantimony(V) (p-vinylbenzoate)₂ (SH-11) (SH-11 aka triisopropenylantimony(V) di(styrenecarboxylate)). FIG. 3B presents contrast curves for SH-11. When SH-11 is developed for 60 seconds in toluene it produces a negative-tone response. When SH-11 is developed for 60 seconds in aqueous 5.2 mM TMAH it produces a positive-tone response.

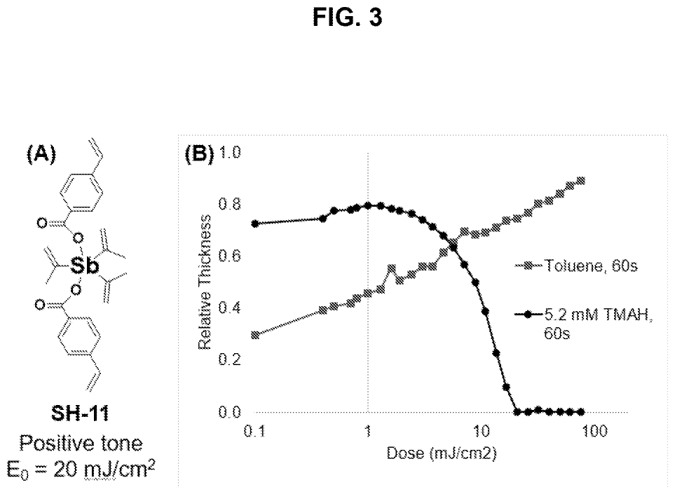

FIG. 4 presents structures of embodiments disclosed herein, wherein M represents some organometallic fragment containing a highly EUV absorbing metal. The ligand bound to the metal is a benzoate group with a vinyl group substituted at the 2, 3 or 4 position.

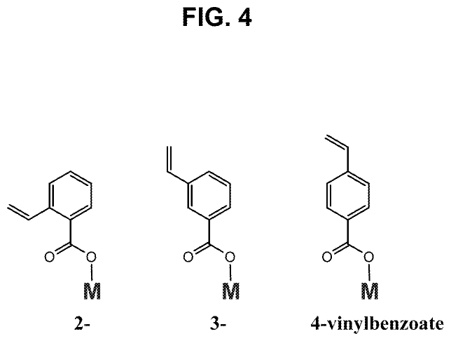

FIG. 5 presents three example positive-tone contrast curves for antimony complexes of the type R₃Sb(4-vinylbenzoate)₂. All three compounds were developed for 60 seconds in 2.5 mM sodium hydroxide. *A zero dose point is included in this figure showing the resist dark loss (relative thickness of unexposed resist after development).

FIG. 6 presents three additional example positive-tone contrast curves for antimony complexes of the type R₃Sb(4-vinylbenzoate)₂. JG-238 and JP-30 were developed in 2.6 mM TMAH for 10 seconds. JG-229 was developed in 5.2 mM TMAH for 10 seconds. *A zero dose point is included in this figure showing the resist dark loss (relative thickness of unexposed resist after development).

FIG. 7 presents contrast curve of diphenyltellurium (IV) (4-vinylbenzoate)₂ (MM-28) developed in an aqueous solution containing 5 wt % isopropanol and 0.052 N TMAH.

FIG. 8 presents a dense line patterning for SH-11 exposed to 44 mJ/cm² EUV radiation and developed in 2.6 mM TMAH for 60 s (FIG. 8A, FIG. 8B and FIG. 8C). Dense line patterning for NU-111 exposed to 53±5 mJ/cm² and developed in 2.5 mM NaOH for 60 s (FIG. 8D, FIG. 8E and FIG. 8F). Labels above columns indicate pitch. Images taken at 100 k× magnification.

FIG. 9 presents NU-111 dense-line patterning with 44 nm pitch. Resist film was exposed to 53±5 mJ/cm² and developed in 2.5 mM NaOH for 60 s. Images taken at 100 k× magnification.

FIG. 10 presents ablation curves for SH-11, JG-11, NU-111 and NU-136. Relative thickness curves plotted after exposure with no development. Resists were exposed to EUV, and thickness measurements were collected for each exposure spot. Relative thickness was plotted against the dose received as in a typical contrast curve. *A zero dose point is included in this figure showing the resist dark loss (relative thickness of unexposed resist).

FIG. 11 presents an example of contrast curve chips that were annotated with locations of ellipsometry measurements. 1-25b are all exposure spots in order of increasing dose. Spots Oa and Ob are unexposed locations and were averaged to give a zero-dose thickness measurement. Spots 25a and 25b are replicate exposures of the highest dose and were averaged to give the final thickness.

FIG. 12 presents an electron beam (2000 eV) contrast curve of SH-11 developed in aqueous 2.6 mM TMAH for 60 seconds. Doses are reported as the exposure time in seconds.

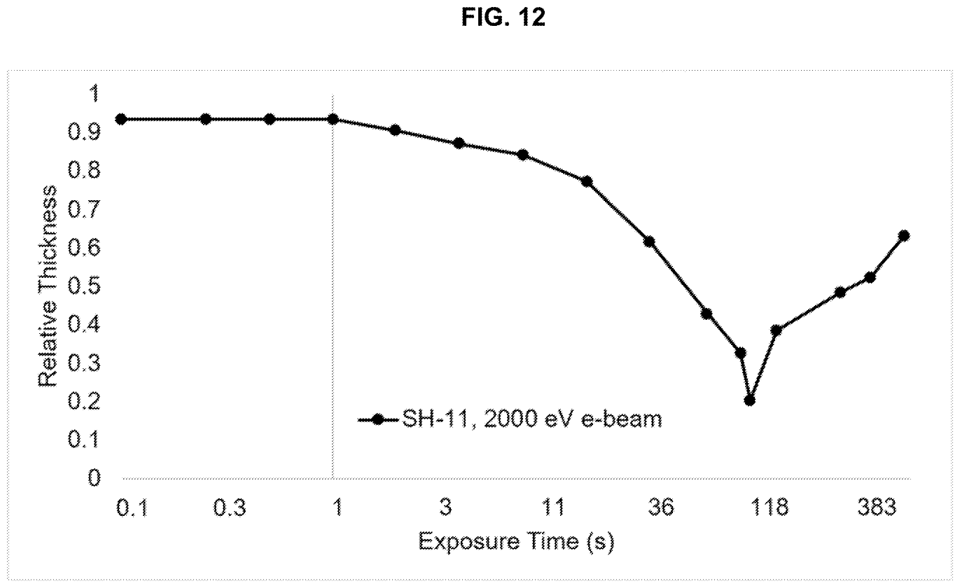

FIG. 13 presents ligand substitutions for compounds of the type R₃Sb(O₂CR′)₂ chosen to elucidate which ligands result in a positive-tone resist.

FIG. 14 presents chemical structures of twelve triorganoantimony dicarboxylates. These compounds were synthesized and evaluated as resists for EUV lithography. Each ligand was chosen to better understand the structure-activity relationship in organoantimony dicarboxylate resists.

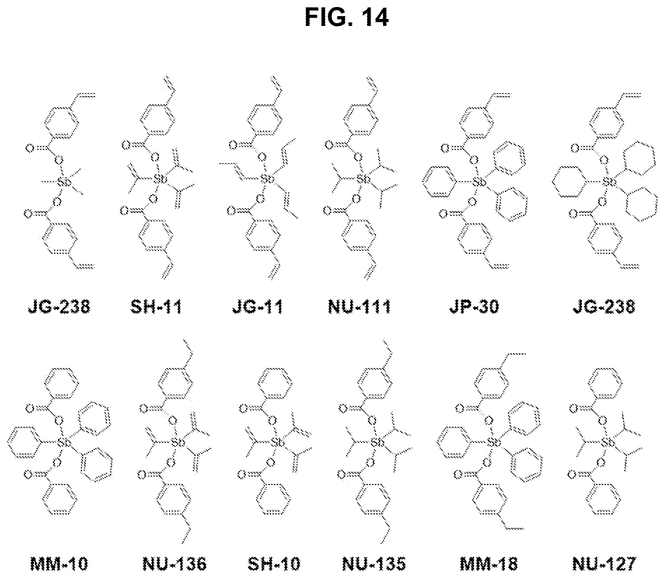

FIG. 15 presents chemical structures and contrast curves of tri(isopropenyl)antimony (p-vinylbenzoate)₂ (SH-11), tri(propenyl)antimony (p-vinylbenzoate)₂ (JG-11) and tri(isopropyl)antimony (p-vinylbenzoate)₂ (NU-111). All three are positive-tone compounds when developed for 60 second in 2.5 mM sodium hydroxide. *A zero dose point is included in this figure showing the resist dark loss (relative thickness of unexposed resist after development).

FIG. 16 presents chemical structures and contrast curves of tri(methyl)antimony (p-vinylbenzoate)₂ (JG-229), tri(phenyl)antimony (p-vinylbenzoate)₂ (JP-30) and tri(cyclohexyl)antimony (p-vinylbenzoate)₂ (JG-238). JG-238 and JP-30 were developed in 2.6 mM TMAH for 10 seconds. JG-229 was developed in 5.2 mM TMAH for 10 seconds. *A zero dose point is included in this figure showing the resist dark loss (relative thickness of unexposed resist after development).

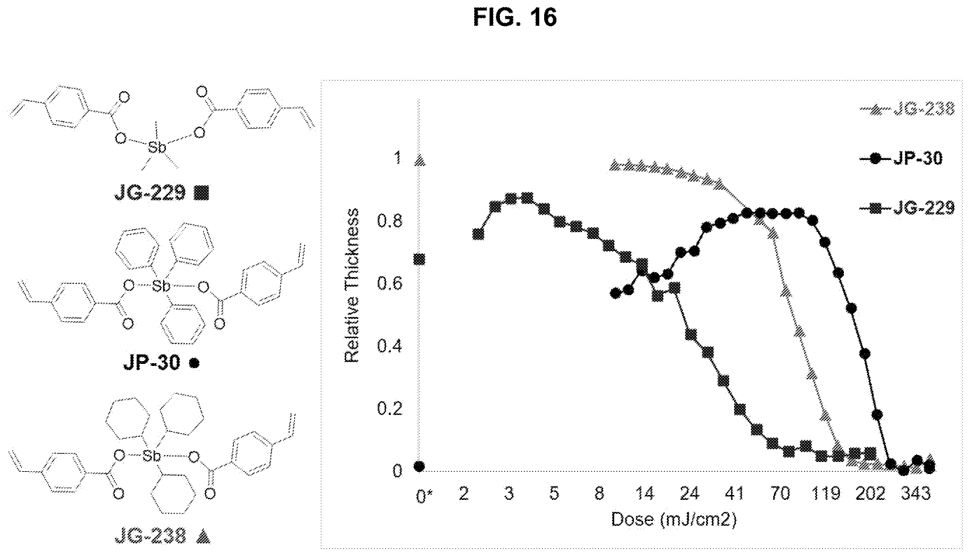

FIG. 17 presents thin films of SH-11 were exposed to a range of EUV exposure doses and developed for 60 seconds in 0, 1, 2.5, 5, 10 and 25 mM concentrations of sodium hydroxide resulting in the above contrast curves. The measured pH of the developer solutions is shown in parenthesis. *A zero dose point is included in this figure showing the resist dark loss (relative thickness of unexposed resist after development).

FIG. 18 presents three possible EUV induced decomposition pathways are shown for photoresist of the type R₃Sb(O₂CR′)₂. Photolysis of (1) the antimony-carbon bond, (2) the antimony-oxygen bond or (3) the antimony-oxygen bond resulting in decarboxylation. *As the exact intermediates are unknown an asterisk (*) is shown to represent a radical, cation, anion, radical-cation or radical-anion.

FIG. 19A presents mass spectrum of outgassed species during exposure to EUV. FIG. 19B present outgassing mass spectrum during exposure to a 2000 eV electron-beam. Mass ranges selected to show the masses corresponding to resist R- and R′-groups. R-group fragments are observed in EUV and e-beam outgassing for all compounds. The R′-group is observed only for NU-136 during EUV and e-beam exposure. In FIG. 19B the y-axis was expanded for the higher amu range to reveal lower intensity signals observed in the mass spectrum.

FIG. 20 presents simplified decomposition pathways with tabulated peaks observed in outgassing for tri(isopropenyl)antimony (p-vinylbenzoate)₂ (SH-11), tri(propenyl)antimony di(p-ethylbenzoate) (NU-136), tri(isopropyl)antimony (p-vinylbenzoate)₂ (NU-111), tri(phenyl)antimony (p-vinylbenzoate)₂ (JP-30), tri(isopropenyl)antimony di(acrylate) (JG-228) and tri(cyclohexyl)antimony (p-vinylbenzoate)₂ (JG-238). For all outgassing analyzed, CO₂ and the R-group were observed in the mass spectrum.

FIG. 21 presents possible photo-induced reaction pathways for R₃Sb (p-vinylbenzoate)₂ resists. Numbers and letters used to identify steps or reactions for discussion. An asterisk (*) next to an atom or group could be a radical, cation, anion, radical-cation or radical-anion. **R(—H) symbolizes an R-group which has lost one hydrogen atom.

FIG. 22 presents the structure of compound JP-30 and a graphic illustration of JP-30's positive-tone contrast curve when developed in 5% TMAH (i.e., 5% of a standard 0.26 N TMAH developer diluted with deionized water).

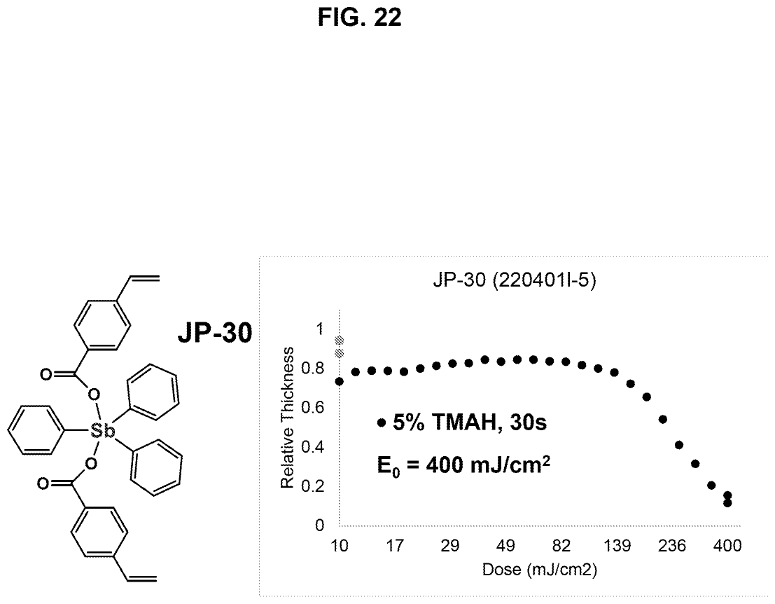

FIG. 23 presents the structure of compound JN-1 and graphic illustrations of JN-1's positive-tone contrast curves when developed in 5% and 7% TMAH, respectively (i.e., 5% and 7% of a standard 0.26 N TMAH developer diluted with deionized water).

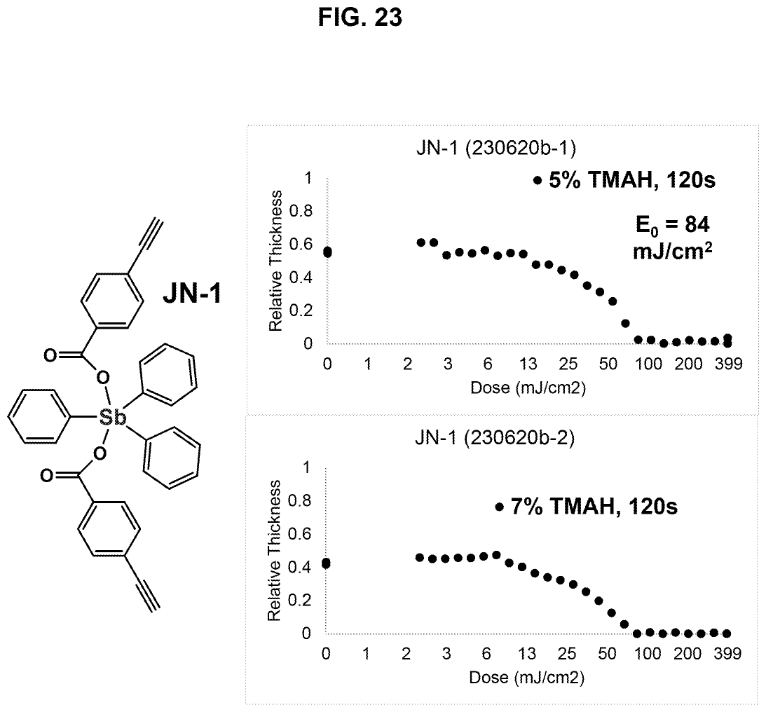

FIG. 24 presents the structure of the dinuclear compound RB-129 and graphic illustrations of RB-129's positive-tone contrast curve and negative-tone contrast curve when developed in 10% TMAH and 2-Heptanone, respectively (i.e., 10% of a standard developer diluted with deionized water).

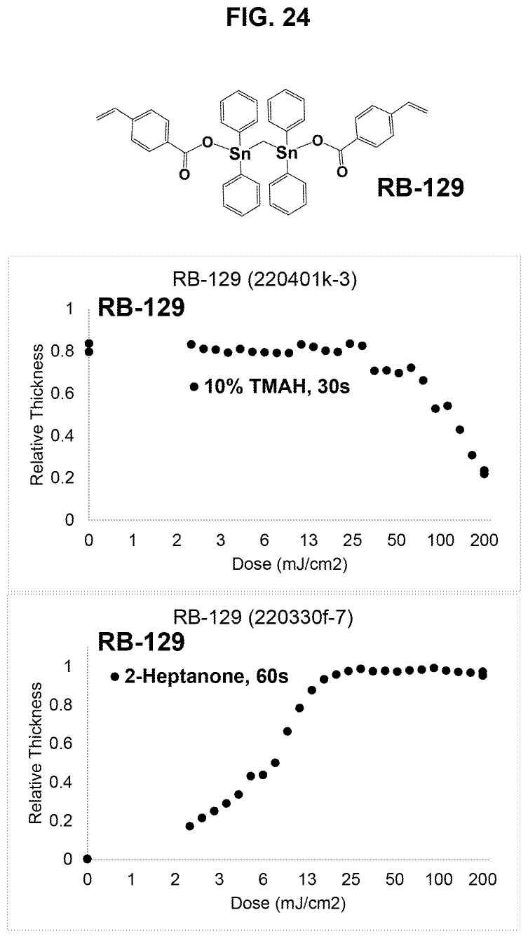

FIG. 25 presents the structure of compound RB-129 and negative-tone imaging when developed in 2-Heptanone.

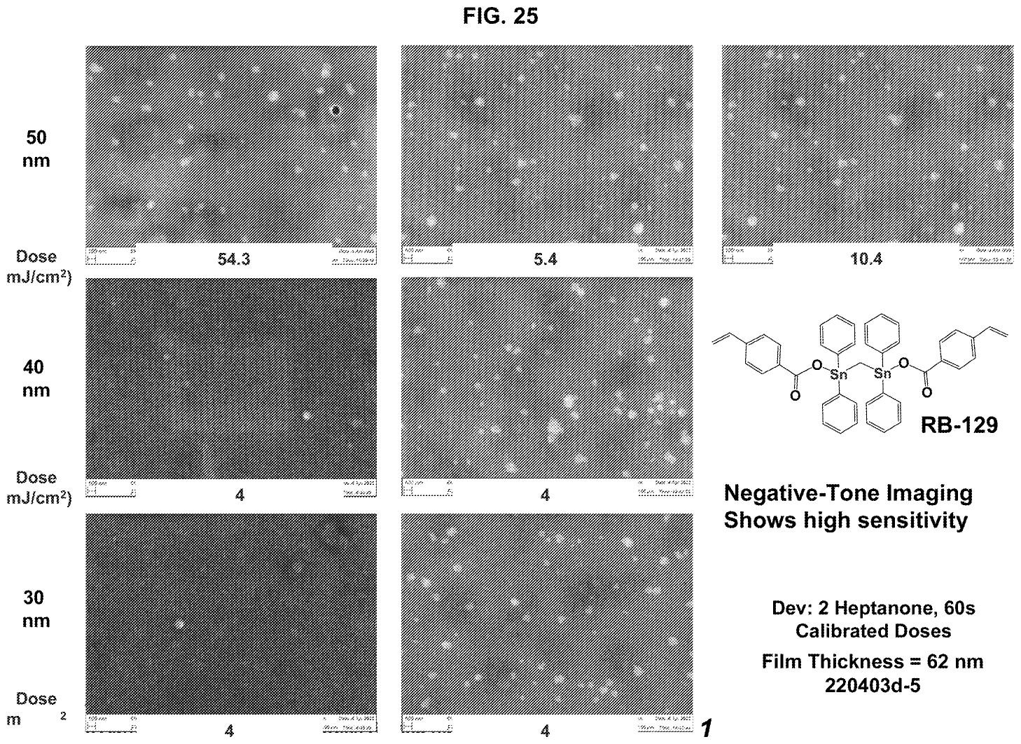

FIG. 26 presents the structure of compound RB-129 and positive-tone imaging when developed in 10% TMAH (i.e., 10% of a standard developer diluted with deionized water).

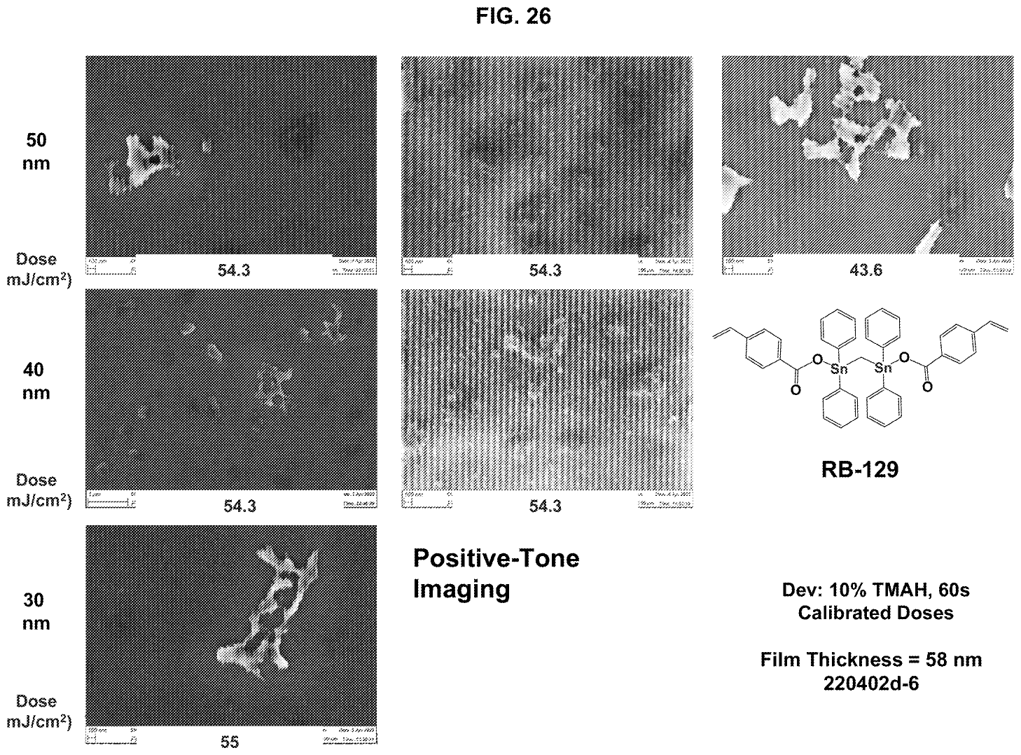

FIG. 27 presents the structures of compounds MM-28 and JH-8 and graphic illustrations of contrast curves when the compounds are developed in 5% IPA in 0.052N TMAH. The contrast curves indicate the importance of the styrene carboxylate ligand to provide a positive-tone contrast curve in the tellurium-based compounds.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### Definitions

As used in the present specification, the following words and phrases are generally intended to have the meanings as set forth below, except to the extent that the context in which they are used indicates otherwise.

As used herein, the singular forms “a”, “an”, and “the” include plural references unless the context clearly dictates otherwise. Thus, for example, references to “a compound” include the use of one or more compound(s). “A step” of a method means at least one step, and it could be one, two, three, four, five or even more method steps.

As used herein the terms “about,” “approximately,” and the like, when used in connection with a numerical variable, generally refers to the value of the variable and to all values of the variable that are within the experimental error (e.g., within the 95% confidence interval [CI 95%] for the mean) or within ±10% of the indicated value, whichever is greater.

As used herein the term “alkyl” refers to C₁₋₂₀ inclusive, linear (i.e., “straight-1 s chain”), branched, or cyclic, saturated or at least partially and in some cases fully unsaturated (i.e., alkenyl and alkynyl) hydrocarbon chains, including for example, methyl, ethyl, propyl, isopropyl, butyl, isobutyl, tert-butyl, pentyl, hexyl, octyl, ethenyl, propenyl, butenyl, pentenyl, hexenyl, octenyl, butadienyl, propynyl, butynyl, pentynyl, hexynyl, heptynyl, and allenyl groups. “Branched” refers to an alkyl group in which a lower alkyl group, such as methyl, ethyl or propyl, is attached to a linear alkyl chain. “Lower alkyl” refers to an alkyl group having 1 to about 8 carbon atoms (i.e., a C₁₋₈ alkyl), e.g., 1, 2, 3, 4, 5, 6, 7, or 8 carbon atoms. “Higher alkyl” refers to an alkyl group having about 10 to about 20 carbon atoms, e.g., 10, 11, 12, 13, 14, 15, 16, 17, 18, 19, or 20 carbon atoms. In certain embodiments, “alkyl” refers to C₁₋₃ straight-chain alkyls. In other embodiments, “alkyl” refers to C₁₋₈ branched-chain alkyls. In embodiments, alkyl groups can optionally be substituted (a “substituted alkyl”) with one or more alkyl group substituents, which can be the same or different. The term “alkyl group substituent” includes but is not limited to alkyl, substituted alkyl, halo, arylamino, acyl, hydroxyl, aryloxyl, alkoxyl, alkylthio, arylthio, aralkyloxyl, aralkylthio, carboxyl, alkoxycarbonyl, oxo, and cycloalkyl. There can be optionally inserted along the alkyl chain one or more oxygen, sulfur or substituted or unsubstituted nitrogen atoms, wherein the nitrogen substituent is hydrogen, lower alkyl (also referred to herein as “alkylaminoalkyl”), or aryl. Thus, as used herein, the term “substituted alkyl” includes alkyl groups, as defined herein, in which one or more atoms or functional groups of the alkyl group are replaced with another atom or functional group, including for example, alkyl, substituted alkyl, halogen, aryl, substituted aryl, alkoxyl, hydroxyl, nitro, amino, alkylamino, dialkylamino, sulfate, and mercapto.

As used herein, the term “heteroalkyl” by itself or in combination with another term means, unless otherwise stated, a stable straight or branched chain alkyl group consisting of the stated number of carbon atoms and one or two heteroatoms of O, N, and S, and wherein the nitrogen and sulfur atoms may be optionally oxidized and the nitrogen heteroatom may be optionally quaternized. In embodiments, the heteroatom(s) may be placed at any position of the heteroalkyl group, including between the rest of the heteroalkyl group and the fragment to which it is attached, as well as attached to the most distal carbon atom in the heteroalkyl group. Non-limiting examples include: —O—CH₂—CH₂—CH₃, —CH₂—CH₂—CH₂—OH, —CH₂—CH₂CH₂—NH—CH₃, and —CH₂—S—CH₂—CH₃. In embodiments, up to two heteroatoms may be consecutive, such as, for example, —CH₂—NH—OCH₃, or —CH₂—CH₂—S—S—CH₃. In embodiments, heteroalkyl groups have 1-12 carbons.

As used herein, the term “alkenyl,” denotes a monovalent group derived from a hydrocarbon moiety containing at least two carbon atoms and at least one carbon-carbon double bond. In embodiments, the double bond may or may not be the point of attachment to another group. Alkenyl groups (e.g., C₂-C₈-alkenyl) include, but are not limited to, for example, ethenyl, propenyl, prop-1-en-2-yl, butenyl, 1-methyl-2-buten-1-yl, heptenyl, octenyl and the like.

As used herein, the term “alkynyl,” denotes a monovalent group derived from a hydrocarbon moiety containing at least two carbon atoms and at least one carbon-carbon triple bond. In certain embodiments, the alkynyl group employed in the disclosure contains 2-20 carbon atoms. In some embodiments, the alkynyl group employed in the disclosure contains 2-15 carbon atoms. In another embodiment, the alkynyl group employed contains 2-10 carbon atoms. In still other embodiments, the alkynyl group contains 2-8 carbon atoms. In still other embodiments, the alkynyl group contains 2-5 carbon atoms. Representative alkynyl groups include, but are not limited to, ethynyl, 1-propynyl, 2-propynyl, 1-butynyl, 2-butynyl, 1-pentynyl, 2-pentynyl, 1-hexynyl, 2-hexynyl and the like, which may bear one or more substituents. Alkynyl group substituents include, but are not limited to, any of the substituents described herein, that result in the formation of a stable moiety. Non-limiting examples of alkynyl as used herein includes alkynyl carboxylate.

As used herein, the term “halo” or “halogen” alone or as part of another substituent means, unless otherwise stated, a fluorine, chlorine, bromine, or iodine atom.

“Cyclic” and “cycloalkyl” refer to a non-aromatic mono- or multicyclic ring system of about 3 to about 10 carbon atoms, e.g., 3, 4, 5, 6, 7, 8, 9, or 10 carbon atoms. In embodiments, a cycloalkyl group can be optionally partially unsaturated. In embodiments, the cycloalkyl group also can be optionally substituted with an alkyl group substituent as defined herein, oxo, and/or alkylene. In embodiments, there can be optionally inserted along the cyclic alkyl chain one or more oxygen, sulfur or substituted or unsubstituted nitrogen atoms, wherein the nitrogen substituent is hydrogen, alkyl, substituted alkyl, aryl, or substituted aryl, thus providing a heterocyclic group. Non-limiting examples of monocyclic cycloalkyl rings include cyclopentyl, cyclohexyl, and cycloheptyl. Non-limiting examples of multicyclic cycloalkyl rings include adamantyl, octahydronaphthyl, decalin, camphor, camphane, and noradamantyl.

As used herein, the term “heterocycloalkyl” or “heterocyclyl” refers to a heteroalicyclic group including one to four ring heteroatoms each selected from O, S, and N. In embodiments, each heterocyclyl group has from 3 to 10 atoms in its ring system, with the proviso that the ring of said group does not contain two adjacent O or S atoms. In embodiments, heterocyclyl substituents may be alternatively defined by the number of carbon atoms, e.g., C₂-C₈-heterocyclyl indicates the number of carbon atoms contained in the heterocyclic group without including the number of heteroatoms. For example, a C₂-C₈-heterocyclyl will include an additional one to four heteroatoms. In embodiments, the heterocyclyl group has less than three heteroatoms. In embodiments, the heterocyclyl group has one to two heteroatoms. In embodiments, the heterocycloalkyl group is fused with an aromatic ring. In embodiments, nitrogen and sulfur heteroatoms may be optionally oxidized, and the nitrogen atom may be optionally quaternized. The heterocyclic system may be attached, unless otherwise stated, at any heteroatom or carbon atom that affords a stable structure.

As used herein, the term “aromatic” refers to a carbocycle or heterocycle with one or more polyunsaturated rings and having aromatic character, i.e., having (4n+2) delocalized π (pi) electrons, where n is an integer.

The term “aryl” is used herein to refer to an aromatic substituent that can be a single aromatic ring, or multiple aromatic rings that are fused together, linked covalently, or linked to a common group, such as, but not limited to, a methylene or ethylene moiety. The common linking group also can be a carbonyl, as in benzophenone, or oxygen, as in diphenylether, or nitrogen, as in diphenylamine. In embodiments, the term “aryl” specifically encompasses heterocyclic aromatic compounds. The aromatic ring(s) can include phenyl, naphthyl, biphenyl, diphenylether, diphenylamine and benzophenone, among others. In particular embodiments, the term “aryl” means a cyclic aromatic including about 5 to about 10 carbon atoms, e.g., 5, 6, 7, 8, 9, or 10 carbon atoms, and including 5- and 6-membered hydrocarbon and heterocyclic aromatic rings. In embodiments, an aryl group can be optionally substituted (a “substituted aryl”) with one or more aryl group substituents, which can be the same or different, wherein “aryl group substituent” includes alkyl, substituted alkyl, aryl, substituted aryl, aralkyl, hydroxyl, alkoxyl, aryloxyl, aralkyloxyl, carboxyl, acyl, halo, nitro, alkoxycarbonyl, aryloxycarbonyl, aralkoxycarbonyl, acyloxyl, acylamino, aroylamino, carbamoyl, alkylcarbamoyl, dialkylcarbamoyl, arylthio, alkylthio, alkylene, and —NR′R″, wherein R′ and R″ can each be independently hydrogen, alkyl, substituted alkyl, aryl, substituted aryl, and aralkyl. Thus, as used herein, the term “substituted aryl” includes aryl groups, as defined herein, in which one or more atoms or functional groups of the aryl group are replaced with another atom or functional group, including for example, alkyl, substituted alkyl, halogen, aryl, substituted aryl, alkoxyl, hydroxyl, nitro, amino, alkylamino, dialkylamino, sulfate, and mercapto. Non-limiting examples of aryl groups include, but are not limited to, cyclopentadienyl, phenyl, furan, thiophene, pyrrole, pyran, pyridine, imidazole, benzimidazole, isothiazole, isoxazole, pyrazole, pyrazine, triazine, pyrimidine, quinoline, isoquinoline, indole, carbazole, and the like.

As generally discussed herein, a structure represented generally by the formula:

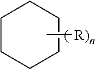

as used herein refers to a ring structure, for example, but not limited to a 3-carbon, a 4-carbon, a 5-carbon, a 6-carbon, and the like, aliphatic and/or aromatic cyclic compound, including a saturated ring structure, a partially saturated ring structure, and an unsaturated ring structure as defined herein, including a substituent R group. In embodiments, the R group can be present or absent, and when present, one or more R groups can each be substituted on one or more available carbon atoms of the ring structure. The presence or absence of the R group and number of R groups is determined by the value of the integer n. Each R group, if more than one, is substituted on an available carbon of the ring structure rather than on another R group. For example, the structure above where n is 0 to 2 would comprise compound groups including, but not limited to:

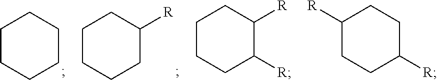

and the like.

In embodiments, a dashed line representing a bond in a cyclic ring structure indicates that the bond can be either present or absent in the ring. That is a dashed line representing a bond in a cyclic ring structure indicates that the ring structure is one of a saturated ring structure, a partially saturated ring structure, and an unsaturated ring structure.

These definitions are intended to supplement and illustrate, not preclude, the definitions that would be apparent to one of ordinary skill in the art upon review of the present disclosure. Before embodiments are further described, it is to be understood that this disclosure is not limited to particular embodiments described, as such may, of course, vary. It is also to be understood that the terminology used herein is for the purpose of describing particular embodiments only and is not intended to be limiting.

Where a range of values is provided, it is understood that each intervening value, to the tenth of the unit of the lower limit unless the context clearly dictates otherwise, between the upper and lower limit of that range and any other stated or intervening value in that stated range, is encompassed within the invention. The upper and lower limits of these smaller ranges may independently be included in the smaller ranges, and are also encompassed within the invention, subject to any specifically excluded limit in the stated range. Where the stated range includes one or both of the limits, ranges excluding either or both of those included limits are also included in the invention.

As used herein, the term “molecular fragment” means, unless otherwise stated, part of a chemical structure with one or more incomplete bonds that requires other groups (e.g. alkyl, aryl, or a metal atom) to give a complete chemical structure. For example, —O₂C— could be combined with two phenyl groups to make phenyl benzoate; —O— could be combined with methyl groups to make dimethyl ether; —PO₄— could be combined with three phenyl groups to make triphenyl phosphate, (C₆H₅O)₃P=O; or —SO₄— could be combined with two phenyl groups to make diphenyl sulfate, (C₆H₅O)₂SO₂.

The term “positive-tone” is used herein to refer to a change in solubility of a resist film in which the resist becomes more soluble as a result of being exposed to actinic radiation under a specific development condition. The term “negative-tone” is used herein to refer to a change in solubility of a resist film in which the resist becomes less soluble as a result of being exposed to actinic radiation under a specific development condition. One resist can exhibit either positive-tone or negative-tone behavior depending upon the developer that is used.

The term actinic radiation refers to light of any wavelength (e.g. 13.5, 193, 248, 365 nm or a broad band mixture of several wavelengths) or charged particles (e.g. electrons or ions with energies from 5-200,000 eV).

The term “dark-loss” is used herein to refer to the amount of thickness a resist film loses during the developments step when that resist has not been exposed to light or actinic radiation.

The term “outgassing” is used herein to refer to the creation and evaporation of small relatively volatile compounds during the exposure to EUV (13.5 nm) light or electron beams under vacuum. These volatile compounds can be analyzed by mass spectrometers attached to the exposure chambers to determine their masses.

The term “ablation” is used herein to refer to the amount of resist film thickness that is lost during the EUV exposure step before the resist film is developed. Often outgassing and ablation occur simultaneously.

The term “photospeed” is used herein to refer to the amount of dose to actinic radiation needed to achieve a pre-determined effect, (e.g. zero film thickness in the contrast curve of a positive-tone resist, or maximum thickness in the contrast curve of a negative resist, or equal-lines and spaces for printing dense-line features using a mask).

The term “SEM” is used herein to refer to scanning electron microscope.

The term “EUV” is used herein to refer to extreme ultraviolet. EUV light has a wavelength of 13.5±0.1 nm and an energy of 92±1 eV.

Unless defined otherwise, all technical and scientific terms used herein have the same meaning as commonly understood by one of ordinary skill in the art to which this invention belongs. Although any methods and materials similar or equivalent to those described herein can also be used in the practice or testing of the present invention, the preferred methods and materials are now described. All publications mentioned herein are incorporated herein by reference to disclose and describe the methods and/or materials in connection with which the publications are cited.

### DETAILED DESCRIPTION

The presently disclosed subject matter will now be described more fully and representative embodiments are shown. The presently disclosed subject matter can, however, be embodied in different forms and should not be construed as limited to the is embodiments set forth herein. Rather, these embodiments are provided so that this disclosure will be thorough and complete, and will fully convey the scope of the embodiments to those skilled in the art.

Throughout the specification and claims, a given chemical formula or name shall encompass all optical and stereoisomers, as well as racemic mixtures where such isomers and mixtures exist.

In embodiments, the present disclosure provides new lithography compositions, methods for forming of resist patterns using a lithography composition, and semiconductor device manufacturing methods using the lithography compositions in a photolithography method of the present disclosure.

In particular, the embodiments disclosed herein are directed to extreme ultra-violet (EUV) positive-tone photoresists containing metallic elements. Incorporation of metals may enhance performance due to high absorptivity, small molecular volume, high material homogeneity and high etch resistance.

Metal containing photoresists (i.e., resists) have been of great interest to the microelectronics industry due to their high EUV absorptivity among other beneficial properties. The earliest metal-containing resists demonstrated to be viable for EUV lithography were hafnium oxide films and nanoparticles. While these resists did not offer large improvement in EUV-absorptivity, they had greatly increased etch selectivity acting as hard masks during pattern transfer. We have focused on MORE (Molecular Organometallic Resists for EUV), which is directed to the synthesis and lithographic evaluation of organometallic compounds as resists. To date well over 1000 compounds have been evaluated containing antimony, bismuth, cobalt, palladium, platinum, tellurium and tin. These prospective photoresists are not only highly efficient at absorbing EUV light but achieve high film homogeneity as they are comprised of a single pure component. In addition to synthesis and lithographic evaluation, we have investigated the photo-mechanisms of our resists to inform the design of future generation resists.

Preparing positive-tone metal containing resists presents challenges. In fact, there is a scarcity of metal containing resists that exhibit positive-tone behavior. Positive-tone photoresists are extremely valuable in the manufacturing of integrated circuits; some features such as contact holes are made preferentially with positive-tone photoresists. The initial positive-tone MORE compounds were oxalate complexes of platinum and palladium. Upon EUV exposure, the oxalate ligands decompose into carbon dioxide resulting in increased solubility in organic solvents. Later a cobalt oxalate complex (NP-1) was discovered to be both negative- and positive-tone depending on the choice of developer. It was thought that the key to positive-tone metal containing resists was in the oxalate ligand.

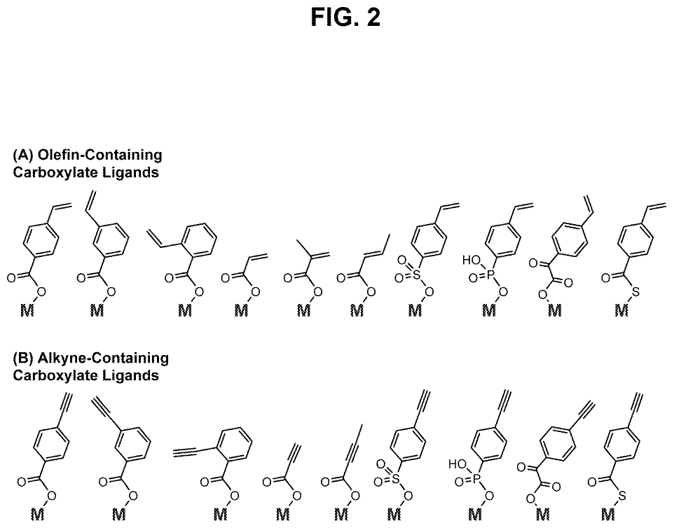

However, we have discovered that some of the most useful ligands used in MORE resists have contained polymerizable olefin groups. During exposure to EUV, resists containing olefins undergo free-radical polymerization resulting in a cross-linked network and generally a decrease in overall solubility and therefore exhibit negative-tone patterning. We have explored the use of olefins in antimony and bismuth complexes of the type R₃M(O₂R′)₂ where M=Sb or Bi, and R or R′ is an organic group. We have also explored the use of olefins in tellurium and tin complexes of the type R₂M(O₂R′)₂ where M=Te or Sn, and R or R′ is an organic group. We have also explored the use of various R ligands and carboxylate ligands, see FIG. 2.

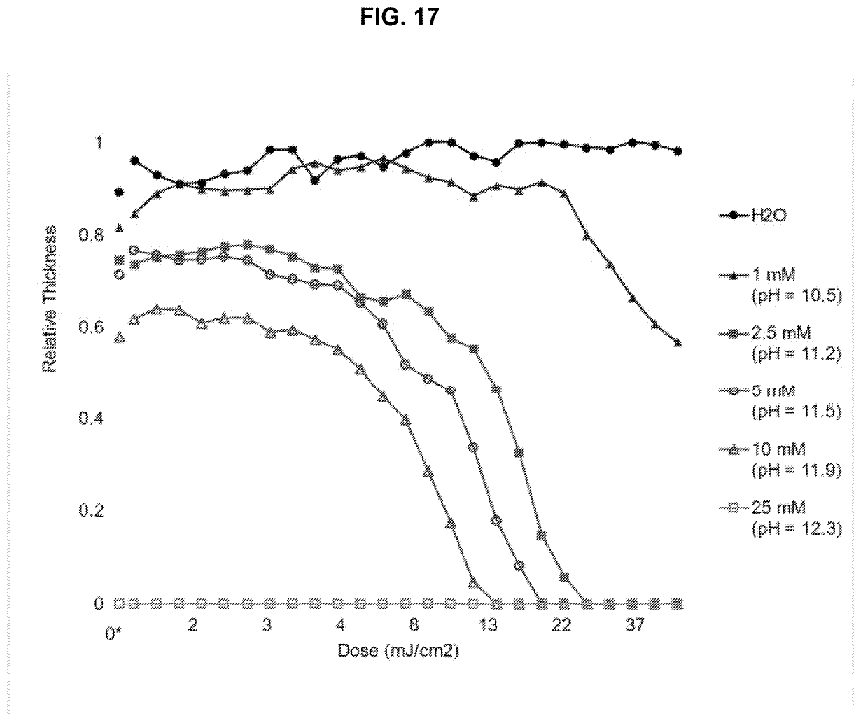

It was our understanding that the inclusion of polymerizable olefins polymerize during exposure to actinic radiation results in a cross-linked network with decreased solubility relative to the pre-exposure resist film. For example, triisopropenylantimony(V) (4-vinybenzoate)₂ shows decreasing solubility in organic developers such as toluene and, 2-heptanone and 4-methyl-2-pentanol with exposure to EUV. However, we have unexpectedly discovered that triisopropenylantimony(V) (4-vinybenzoate)₂ becomes increasingly soluble in dilute aqueous tetramethylammonium hydroxide (TMAH) solution (or dilute aqueous NaOH (FIG. 17)), as a function of EUV exposure dose.

In embodiments disclosed herein, the vinylbenzoate ligand (aka styrene carboxylate ligand) utilized to provide positive-tone lithography to mono and multinuclear metal containing resists for use in EUV lithography. Embodiments of the present disclosure include metals from the main group that strongly absorb EUV light, such as: tellurium, antimony, tin, iodine, bismuth and indium. Despite previous reports of negative-tone behavior in metal containing EUV resists with ligands containing polymerizable olefins, we have demonstrated increased solubility in aqueous base for resists containing antimony, tin, bismuth and tellurium in combination with the 4-vinylbenzoate ligand.

In embodiments disclosed herein, various ligands, such as, for example, 2-vinylbenzoate, 3-vinylbenzoate, 4-vinylbenzoate, 2-ethynylbenzoate, 3-ethynylbenzoate, 4-ethynylbenzoate with the main-group metals (e.g. Sb, Sn, Te, Bi), which strongly absorb EUV, are utilized to produce positive-tone metal-containing resists. These ligands can be used to produce positive-tone, mono- and multinuclear complexes of highly EUV-absorbing main group metals. We have discovered that the choice of R-groups used concurrently with vinylbenzoates allows modulation of the positive-tone response as well as other resist properties. R-groups are aromatic or aliphatic hydrocarbon, such as, C1 to C10 alkyl, alkenyl, alkynyl or aromatic hydrocarbons. These R-groups may also contain substituted heteroatoms particularly at the alpha, beta or gamma position. The modulated properties include but are not limited to photospeed, contrast, SEM stability, film homogeneity and quality. Similarly, the choice of metal may be used to modify these properties.

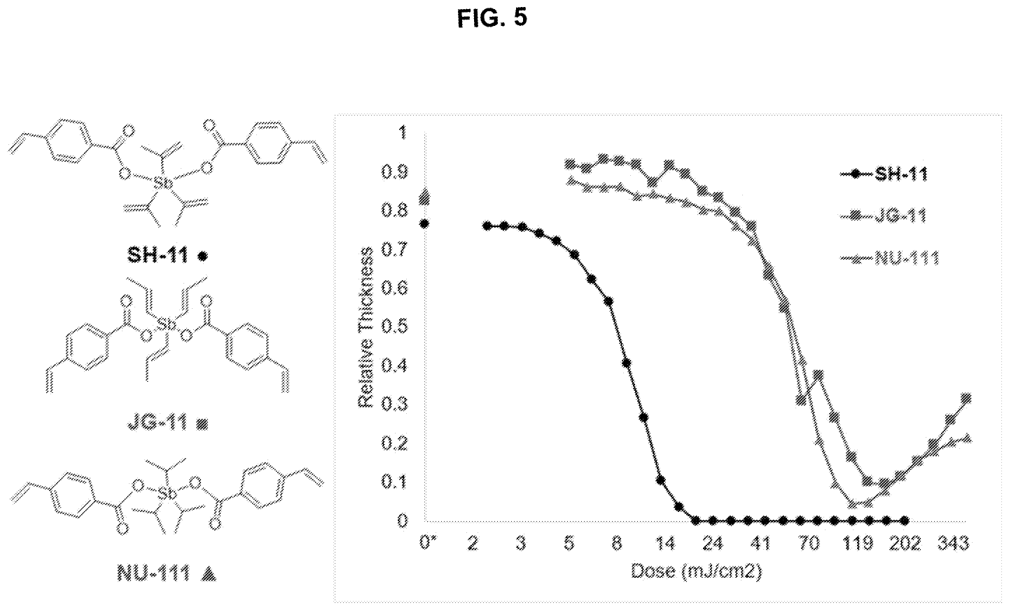

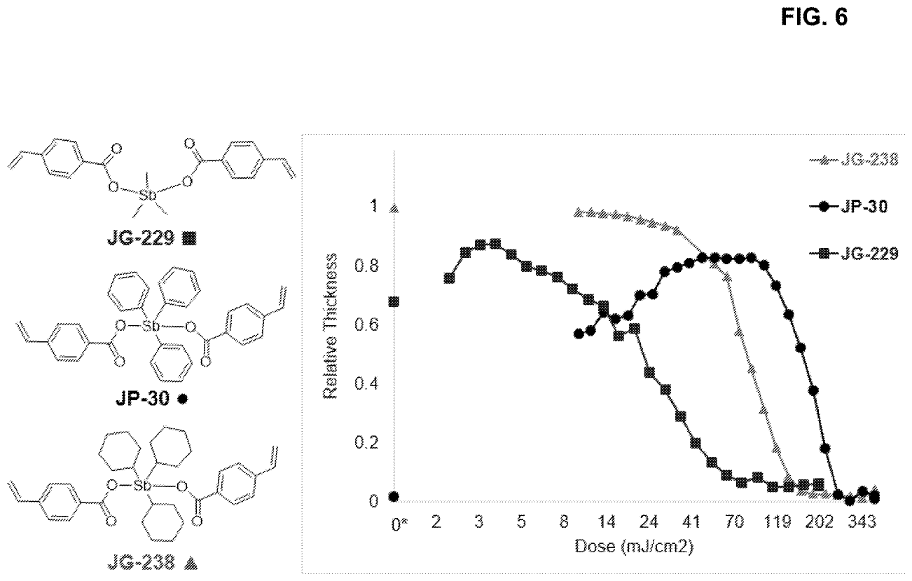

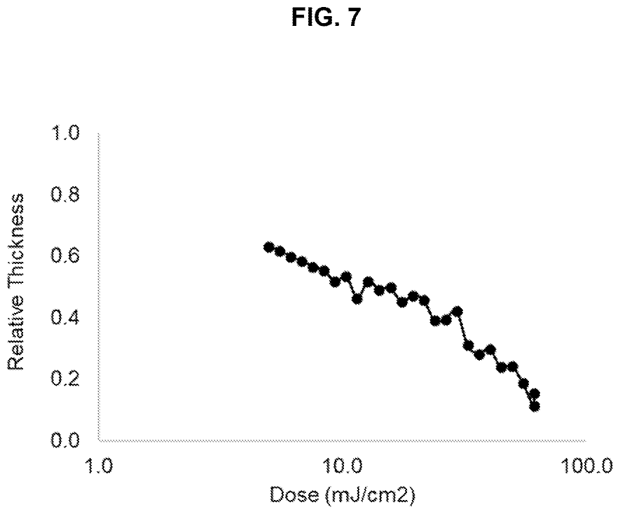

Prior to the current work the 4-vinylbenzoate ligand had only been used in negative-tone resists. We have discovered antimony-containing resists of the type R₃Sb(O₂R′)₂ that show increasing aqueous base solubility in response to EUV light (FIGS. 5, 6 and 13). Additionally, we have found that the compound R₂Te(O₂R′)₂ has shown positive-tone behavior (FIG. 7). The 4-vinylbenzoate group in antimony-containing resists has been shown to result in positive-tone behavior for a wide variety of R-groups. Thus far, this positive-tone behavior has been demonstrated for R-groups including methyl, isopropyl, isopropenyl, propenyl, cyclohexyl and phenyl. This wide variety of R-groups is evidence that the 4-vinylbenzoate group is key to the positive-tone response. The selection of R-groups may also be useful in modulating the EUV response.

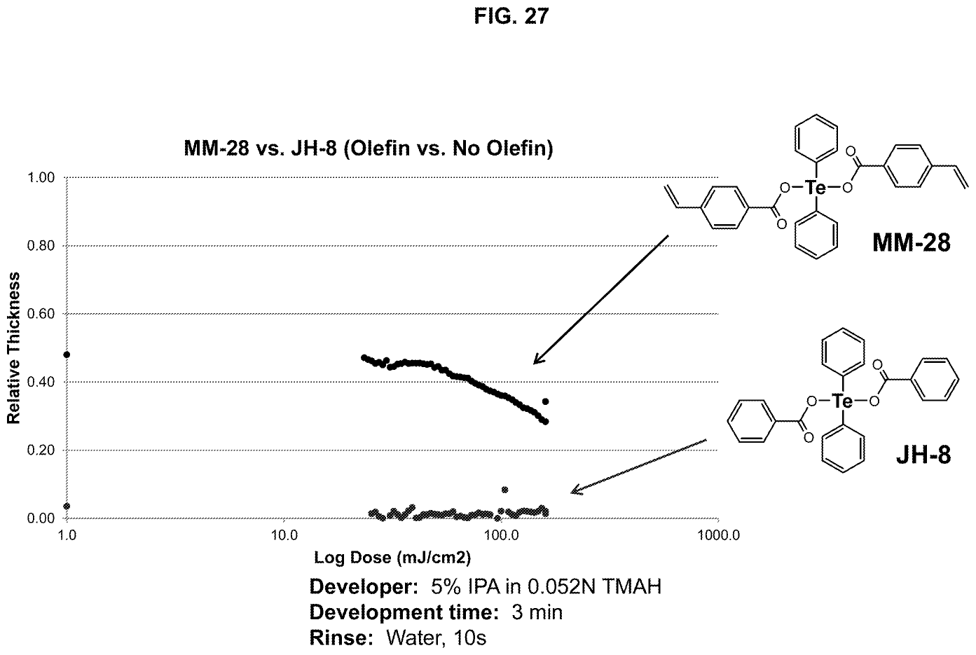

The complex diphenyltellurium(IV) (4-vinylbenzoate)₂ (MM-28) also yields a positive-tone response to EUV when developed in an aqueous base solution containing 5 percent by weight of isopropanol (FIG. 7 and FIG. 27). While this compound does not produce a dose to clear curve indicating promise for patterning, this behavior provides evidence that the 4-vinylbenzoate ligand can be used to produce positive-tone complexes with post-transition metals other than antimony.

We have also demonstrated dense-line patterning for resists of the type R₃Sb (4-vinylbenzoate)₂ when R is isopropyl and isopropenyl. The complex triisopropenylSb(V) (4-vinylbenzoate)₂ (SH-11) showed slightly better sensitivity, however suffered from heavy degradation under the SEM electron beam. The complex triisopropylSb(V) (4-vinylbenzoate)₂ (NU-111) demonstrated dense-line patterning resolving 44 nm pitch upon discovery with no optimization. These results were obtained using interference lithography at the Paul Scherrer Institute.

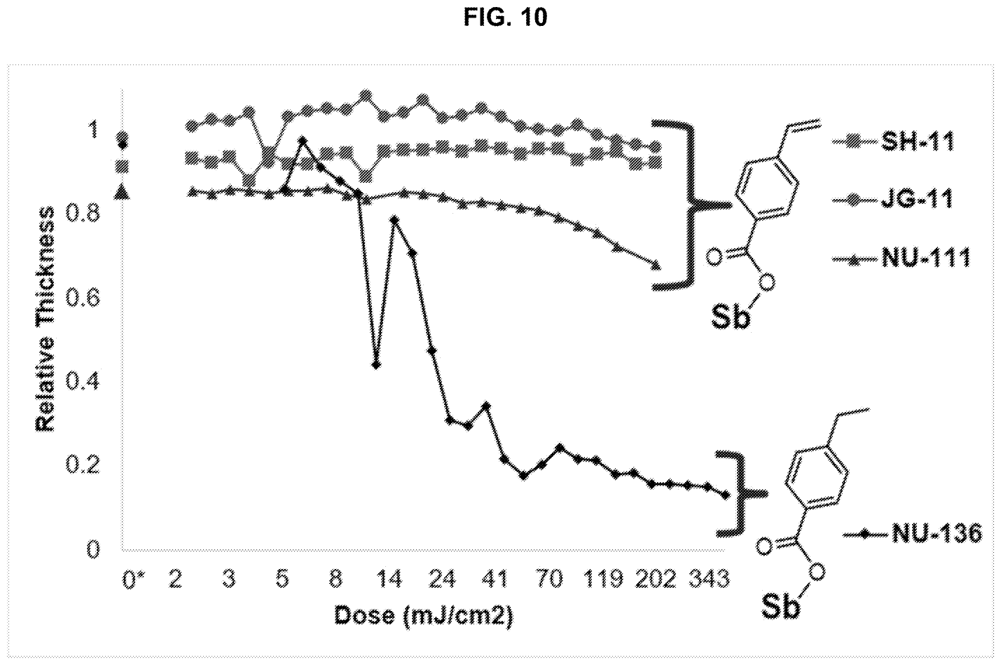

We note that when 4-ethylbenzoate ligand is used in place of the 4-vinylbenzoate ligand, no positive-tone behavior is observed. The only difference between SH-11 and NU-136 is saturation of the terminal olefin on the carboxylate moiety. This substitution results in a dramatic change in the EUV response. During exposure to EUV, NU-136 loses mass at a dramatic rate. At around 54 mJ/cm², NU-136 losses between 80-90% of its original film thickness due to ablation (FIG. 10). SH-11 shows only around 10% film thickness loss at an EUV dose of 200 mJ/cm². This difference is further evidence that the key to positive-tone behavior in this family of resists lies in the 4-vinylbenzoate ligand and specifically the presence of the terminal olefin.

We exposed thin films of pure tri(isopropenyl)antimony (p-vinylbenzoate)₂ SH-11 to 0.1 to 75.4 mJ/cm² of EUV light. These thin films were then developed in either toluene or 2.6 mM aqueous tetramethylammonium hydroxide (TMAH) resulting in positive- and negative-tone responses. SH-11 has the lowest dose to clear (E₀), highest contrast (change in thickness with respect to dose) and best clearing (no film remained for any dose above E₀) of any positive-tone resist that we discovered.

A thin film of SH-11 was exposed to a 2000 eV electron beam and developed for 60 seconds in 2.6 mM TMAH. SH-11 increases in solubility with e-beam exposure dose (when exposed for less than 100 seconds). Unlike exposure to EUV, when exposure to e-beam results in a tone-switch. At lower doses, solubility in aqueous base increases as a function dose until around 100 seconds of exposure after which solubility decreases with all additional exposure. While no true E₀ was observed, an Emin is observed after which each subsequent increase in dose results in increased thickness retention.

Structure Function Analysis of Positive-Tone Organoantimony Dicarboxylates: After the discovery of SH-11, we hypothesized which ligand was responsible for the observed positive-tone response. Our understanding is that styrenecarboxylate and other ligands with polymerizable olefins results in fast negative-tone responses. With this understanding, we thought the isopropenyl ligand was the more likely cause of the positive-tone behavior. To test this, we synthesized many compounds systematically varying the alkyl and carboxylate groups. Early efforts failed to produce new positive-tone resists of the same type.

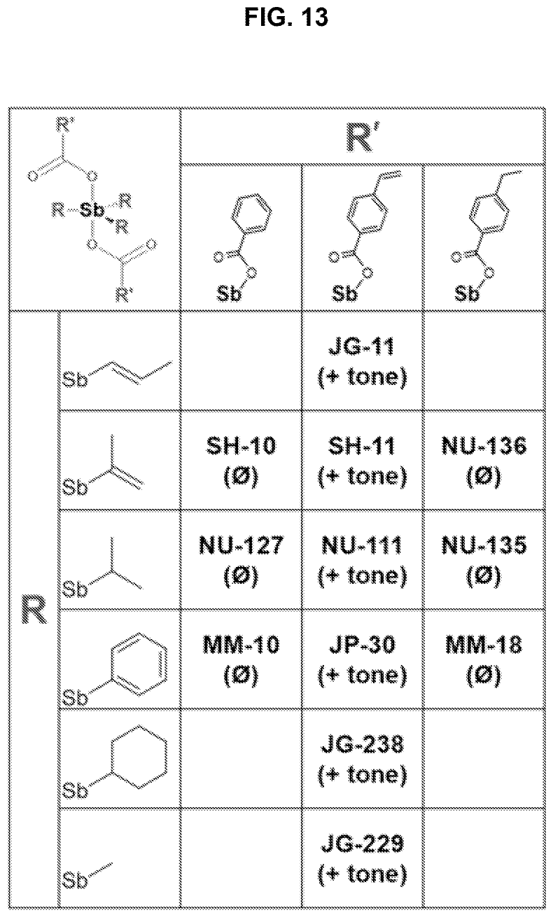

Seeking to elucidate which ligand is principally responsible for the observed positive-tone behavior, we synthesized and evaluated a series of compounds including tri(methyl)antimony (p-vinylbenzoate)₂ (JG-229), tri(propenyl)antimony (p-vinylbenzoate)₂ (JG-11), tri(isopropyl)antimony (p-vinylbenzoate)₂ (NU-111), and tri(cyclohexyl)antimony (p-vinylbenzoate)₂ (JG-238) (FIG. 13). We considered three possibilities for which ligand gives rise to the observed positive-tone response. (1) The isopropenyl ligand due to antimony being bonded with a sp² hybridized carbon, (2) the isopropenyl ligand due to the geometry of the group and (3) the styrenecarboxylate.

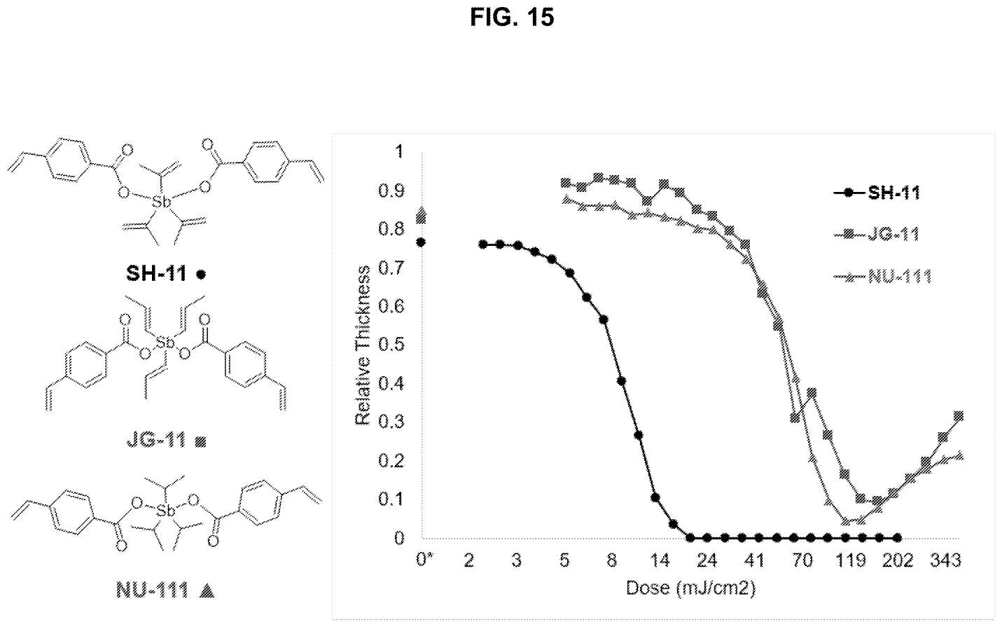

Thin films of SH-11, JG-11 and NU-111 were subjected to a range of EUV exposure doses followed by development in 2.5 mM sodium hydroxide for 60 seconds. All three thin films yield positive-tone contrast curves. JG-11 and NU-111 both have slower photo-speeds (E₀=134 and 111 mJ/cm² respectively) when compared to SH-11 (E₀=20 mJ/cm²) (FIG. 15). All compounds containing the styrenecarboxylate (i.e., (p-vinylbenzoate)₂) ligand yield positive-tone contrast curves when developed in 2.5 mM sodium hydroxide or 2.6 mM TMAH. These results indicate that the styrenecarboxylate ligand is key to positive-tone behavior.

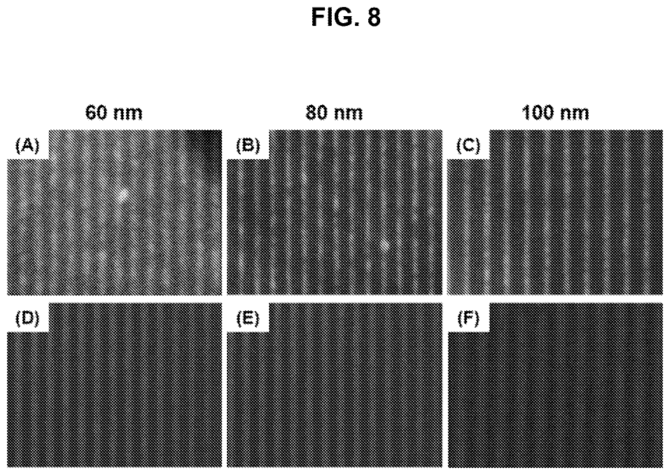

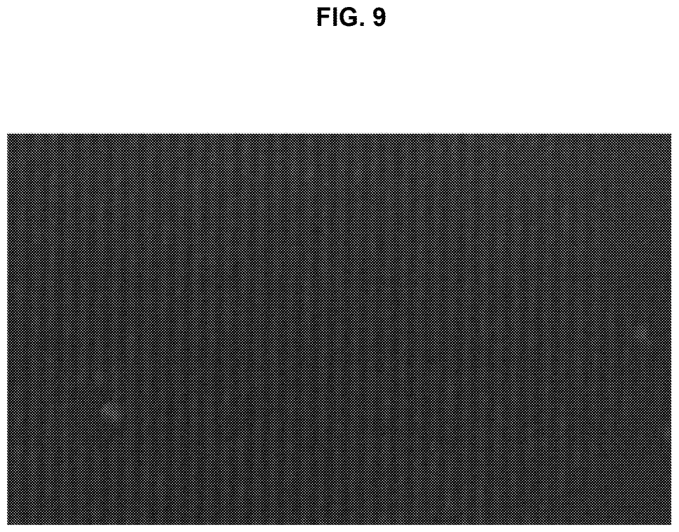

Positive-Tone Dense-Line Patterning: A thin film of SH-11 was exposed to EUV light using interference lithography through a mask containing a dense-line pattern with pitches of 60, 80, 100 and 44 nm (FIGS. 8A, 8B and 8C). The film was then developed in 2.6 mM TMAH for 60 s. SH-11 was found to be capable of dense-line patterning. At a dose of 44 mJ/cm² SH-11 was able to achieve a resolution of 30 nm half pitch. While capable of patterning, the resist film suffered heavy degradation under the electron beam of the SEM making collection of quality images a challenge. Similarly, a thin film of NU-111 demonstrated dense-line patterning albeit at the much higher dose of 53 mJ/cm² and development in a 2.5 mM sodium hydroxide solution (pitches were 60, 80 and 100 nm shown in FIGS. 8D, 8E and 8F). At this dose, NU-111 was able to resolve 22 nm half pitch lines (FIG. 9). Unlike SH-11, NU-111 showed only minor degradation under the electron beam making image collection substantially easier. Unfortunately, NU-111 also tends to crystallize after spin-casting. As a result, patterned lines could only be found in some areas of the exposed film.

Thin Films of SH-11, JG-11, NU-111 and NU-136 were exposed to varying doses of EUV light and thickness of each spot was measured with no development. During exposure of NU-136, film thickness is lost at a tremendous rate at doses less than 54 mJ/cm² before stagnating around 80-90% thickness lost (FIG. 10). The thickness loss is a result of ablation (evaporation of resist material during exposure). Despite differing from NU-136 only by presence of an unsaturation at the carboxylate para position, SH-11 shows a maximum of around 10% thickness loss due ablation. The lack of a polymerizable olefin in NU-136 is suspected to be partly responsible for the observed ablation.

Dependence of Base Concentration on Contrast Curves: Thin films of SH-11 were exposed to EUV and developed in neutral deionized water and aqueous solutions of sodium hydroxide (1 to 25 mM) of varying concentrations (FIG. 17). Development in deionized water reveals no change in film thickness as a function of dose indicating no change in solubility. When developed in 1 mM aqueous sodium hydroxide, the resist film becomes increasingly soluble for all doses over 20 mJ/cm². This establishes the crucial role of base in the positive-tone behavior. A concentration above 1 mM was required to clear the exposed resist under the given conditions but must be less than 25 mM to prevent the unexposed resist from clearing. The 2.5 mM solution was found to be optimal yielding high thickness retention at low doses, sharp contrast, and zero thickness retention for all doses exceeding 22 mJ/cm². The pH of each solution was measured using a vernier lab pro pH meter.

EUV-Induced Decomposition Pathways: Previously, we studied the decomposition pathways of R₃Sb(O₂CR′)₂ photoresists. We have previously reported that volatile compounds resulting from metal-carbon and metal-oxygen bond cleavage are generated during exposure. Breaking of the metal-oxygen bond results in liberation of the carboxylate group. In some cases, breaking the metal-oxygen bond results in decarboxylation and the liberation of carbon dioxide. Pathway (1) is the photolysis of the antimony-carbon bond yielding a free R-group. Pathway (2) is the cleavage of the antimony-oxygen bond resulting in detachment of the carboxylate group. Pathway (3) is the generation of carbon dioxide and a free R′-group. These simplistic representations of the exposure mechanism are used as a framework for understanding and discussing the primary photoinduced decomposition pathways for our resist system.

EUV and e-beam Induced Resist Outgassing: EUV photoresists are known to lose mass during exposure via the evaporation of photoproducts. The characterization of generated volatiles is important to minimize the likelihood of contaminating EUV optics. The identification of these volatiles can also provide insight into the chemical reactions that occur during exposure. Understanding these reactions is both pivotal in understanding the current resist systems, and in designing future generations of positive-tone resists.

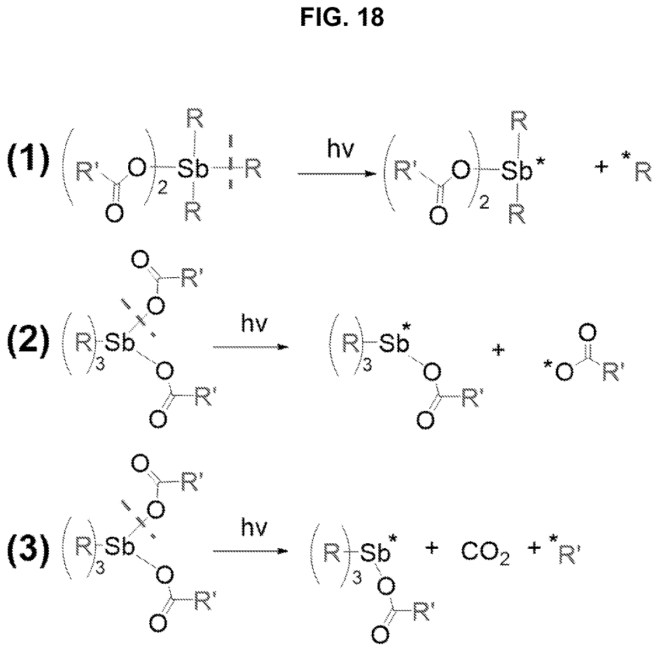

The Denbeaux research group created both the Resist Outgassing eXposure chamber (ROX) and the Electron Resist Interaction Chamber (ERIC). These tools are capable of exposing resist films to EUV and e-beam respectively while simultaneously performing in-situ mass spectrometry. The direct characterization of outgassed species during exposure enabled us to make inferences on the exposure mechanism. Outgassing from three selected compounds of interest all contained fragments predicted by the decomposition pathways (FIG. 18). Carbon dioxide detection in the outgassing mass spectrum was found to be unreliable due to a large background presence in the exposure chamber. Previous EUV experiments showed carbon dioxide outgassing in R₃Sb(O₂CR′)₂ resist. Additionally, carbon dioxide was identified in the outgassing of all resists during electron-beam exposure. These results provide evidence that decarboxylation is ubiquitous in the exposure mechanism of antimony carboxylate resists.

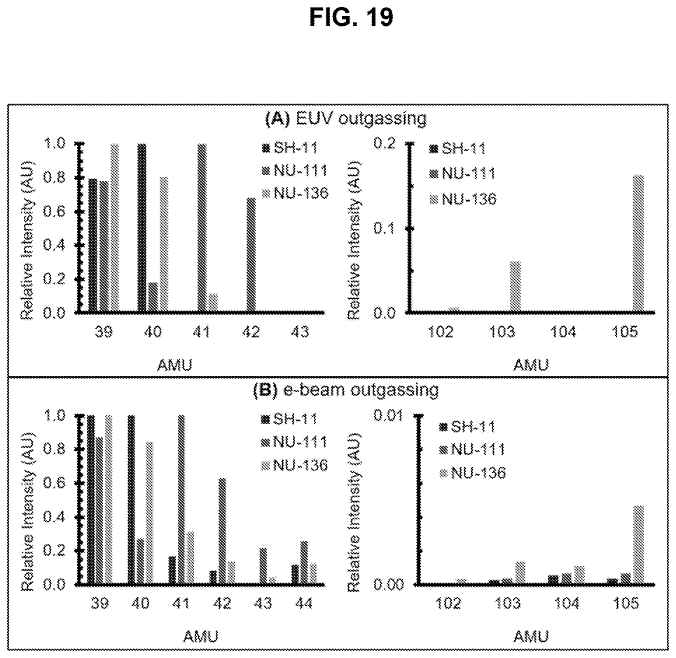

Fragments of the R-group were found for all three samples both during EUV and e-beam exposure (FIG. 19). The two most prominent peaks from the SH-11 and NU-136 outgassing spectra are 40 and 39 amu corresponding to the isopropenyl group after the loss of 1 or 2 hydrogens, respectively. Similarly, the spectrum for NU-111 contained prominent peaks at 42 and 41 amu as was predicted for the isopropyl group after the loss of 1 or 2 hydrogens, respectively. A peak at 105 amu for NU-136 corresponding to an ethylbenzene cation was observed as predicted by Pathway 2 albeit in low quantities during e-beam exposure. The same pathway predicts a peak at 105 amu corresponding to a styrene cation for SH-11 and NU-111 but was not identified in any of the outgassing characterization (FIG. 19). This could be another indication that polymerization occurs for photoresists containing terminal olefins resulting in a nonvolatile R′-group after decarboxylation.

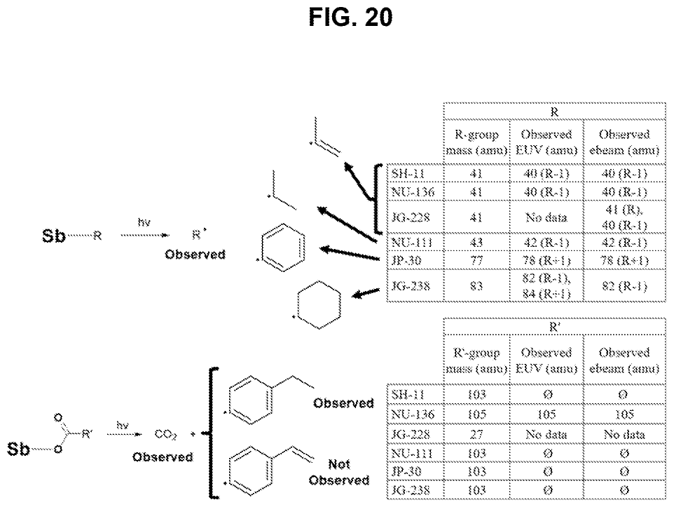

In total, five compounds were exposed to both EUV and e-beam. One compound was exposed only to e-beam. The outgassing mass spectra were analyzed for evidence of R- and R′-groups and can be found tabulated in FIG. 20. All exposures showed evidence of R-group and CO₂ outgassing. Interestingly, isopropyl and isopropenyl groups are detected in the outgassing only after loss of 1 or 2 hydrogen atoms. For example, the isopropyl group is detected as [C₃H₆]⁺ rather than [C₃H₇]⁺. In contrast, the phenyl group of JP-30 is detected having gained one hydrogen atom ([C₆H₆]⁺). Benzene was found previously to be a primary fragment in the outgassing of tri(phenyl)antimony dicarboxylate resists. The relative instability of the phenyl radical when compared to a secondary alkyl radical could explain the absence of a phenyl radical in the outgassing and perhaps lack of positive-tone response for JP-30. NU-136 was the only compound yielding evidence of the R′-group in the outgassing. It should be noted that aside from NU-136, JG-228 was the only other resist with an olefin containing carboxylate other than styrenecarboxylate. The R′-group for JG-228 is simply a vinyl group (—CH═CH₂) and would not be detected in the mass spectrum due to its low mass being outside our detection range of 30-200 amu.

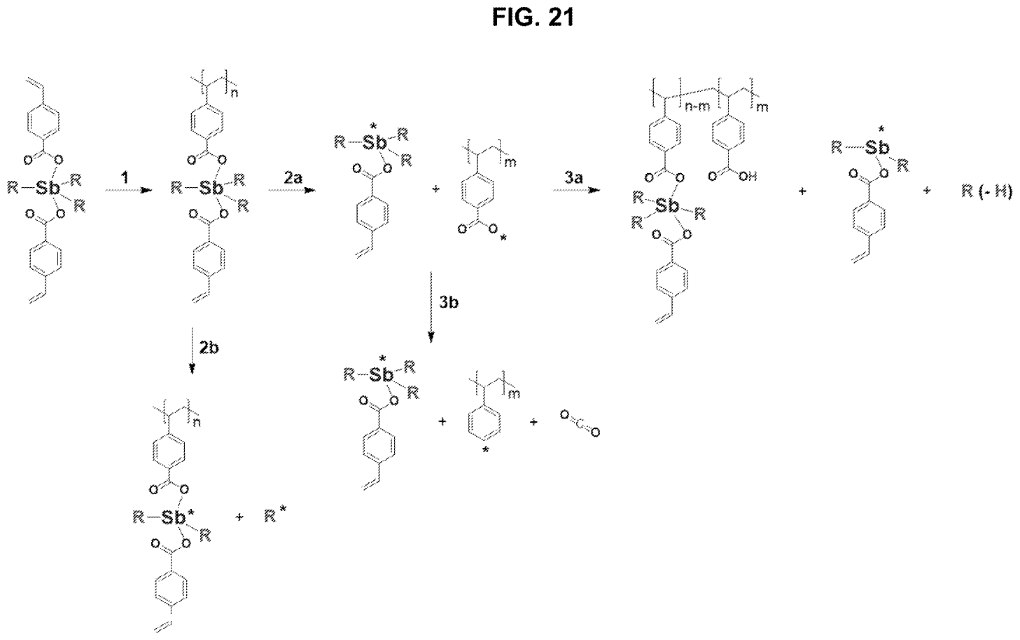

Mechanistic Interpretation: The detailed mechanisms of the exposure of EUV resists is still an area of active debate. Nonetheless, the fundamental steps in the mechanism are clear—a 92 eV EUV photon is absorbed thereby creating an energetic photoelectron and a radical cation (or “hole”). This energetic photoelectron causes additional ionization reactions resulting in the creation of several electrons of varying kinetic energies and still more radical cations, or holes. How specifically, these electrons and holes induce chemical reactions is not understood for conventional chemically amplified photoresists, and even less so for inorganic resists. Nonetheless, we propose here a network of plausible mechanistic steps that are consistent with the structure-function and mass-spectral outgassing experiments presented in this paper (FIG. 21). Since much of evidence for molecular fragmentation is based on positive-ion mass spectroscopy, and we don't have direct evidence of species remaining in the film, we use an asterisk (*) to symbolize a radical, cation, anion, radical-cation or radical-anion.

Step 1: The olefin on the carboxylate group undergoes free-radical polymerization. Previous work with resists containing polymerizable olefins showed that polymerization occurs at low doses resulting in a polymer network in the film. Specifically, a radical, anion, or cation generated during photolysis initiates the polymerization thereby reducing the solubility of the exposed areas and producing negative-tone imaging. Increasing the number of polymerizable olefins relative to non-hydrogen atoms was shown to correlate with the sensitivity of negative-tone resists. Hasan's work demonstrated that molecular weight of a mono-olefin resist system increases as a function of exposure dose providing further evidence of polymerization. Here we show the same polymerization process with subsequent photochemistry resulting in increased aqueous base solubility. In this work, Step 1 is supported by two pieces of evidence: (a) The difference in ablation between the antimony complexes that contain the styrene carboxylate ligand (SH-11, JG-11 and NU-111) and the complex (NU-136) which contains the non-olefinic p-ethylbenzoate ligand; and (b) The difference in mass spectra between this same set of compounds. The compounds containing styrenecarboxylate show no evidence of R′ fragments in their mass spectra, but NU-136 shows evidence of ethylbenzene.

Step 2: The antimony-oxygen bond (Step 2a) or the antimony-carbon bond (Step 2b) is cleaved. Breaking of the antimony-carbon bond results in free R-groups which are detected in all cases in the outgassing mass spectra after the loss of a hydrogen atom. In the case of NU-136 (not shown in FIG. 21) which contained no polymerizable group, breaking of the antimony-oxygen bond results in a free ethylbenzoate group after the loss of CO₂, the ethyl-phenyl group is detected in the outgassing. The presence of all R-groups and ethylbenzoate and the absence of styrenecarboxylate in the outgassing is consistent with Steps 1, 2a and 2b. Breaking of the antimony-oxygen bond after polymerization results in separate fragments containing antimony and a polymer-bound carboxylate.

Step 3b: The antimony-oxygen bond is photolyzed in some fraction of cases results in decarboxylation. Carbon dioxide is detected for all resists in the current work during e-beam exposure and has been previously reported as an outgassed specie from metal-carboxylate resists.

Step 3a: A hydrogen atom is abstracted by the carboxylate fragment resulting in a polymer-bound carboxylic acid (3a). Among the products of Step 3a, one additional polymeric unit is shown to visualize the changing composition of the polymer network. The formation of polymer-bound carboxylic acids is responsible for the increased solubility in alkaline developer. The carboxylate abstracts a hydrogen from an R-group which subsequently eliminates from the metal. This is consistent with the detection of R-groups having lost a hydrogen atom in the outgassing spectra for positive-tone compounds.

We proposed that the change in solubility is a result of an increasing ratio of carboxylic acid to metal carboxylate in the polymer network. The exposed films are insoluble in deionized water as would be expected for a polymeric carboxylic acid. The formation of carboxylic acids is in direct competition with decarboxylation. If decarboxylation is dominant, we would not expect increased solubility in aqueous base as there could be no formation of carboxylic acids. Nevertheless, if formation of carboxylic acids is dominant, breaking too high a fraction of the antimony-oxygen bonds could lead to insoluble antimony species no longer bound to the polymer. This balance of decarboxylation and metal-oxygen bond breaking is consistent with the decreased solubility observed for NU-111 and JG-11 at doses above 120 mJ/cm² (FIG. 15).

We have synthesized and evaluated numerous triorganoantimony dicarboxylates as positive-tone resists. In combination with the styrenecarboxylate (i.e., (p-vinylbenzoate)₂) ligand, isopropenyl, propenyl and isopropyl ligands demonstrated a positive-tone response to EUV radiation. These results indicate that the styrenecarboxylate ligand is key to producing a positive-tone response to EUV or e-beam exposure. The isopropenyl group was shown to have the highest sensitivity (E₀=20 mJ/cm²) compared to propenyl and isopropyl (E₀=134 and 111 mJ/cm², respectively). When the olefin is saturated to an ethyl group, substantial loss of film thickness occurs during exposure. With only around 15% of film thickness remaining, evaluation of solubility change was futile. The ablation could be in part due to the lack of a polymerizable olefin leading to increased volatility after photolysis of metal-oxygen bonds.

Both SH-11 and NU-111 have been successfully used in dense-line patterning. SH-11 was able to resolve 30 nm half-pitch lines with a dose of 44 mJ/cm² but suffered from heavy degradation during SEM imaging. With each scan of the electron beam the patterns became increasingly dark and faint. NU-111 was able to resolve 22 nm half-pitch lines at a dose of around 53 mJ/cm². NU-111 shows vastly improved stability in the SEM compared to SH-11, but tends to form a crystalline, non-amorphous, thin film.

The outgassing from seven resists was analyzed via in-situ mass spectrometry during exposure to EUV and e-beam. Resist fragments corresponding to the breaking of the metal-carbon bond and metal-oxygen bond were observed for all resists. No resist containing the styrenecarboxylate group (i.e., (p-vinylbenzoate)₂) yielded evidence of vinylbenzene in the outgassing. Fragments corresponding to ethylbenzene were observed for the containing resist, NU-136. We suspect the presence of ethylbenzene and the absence of vinylbenzene is due to polymerization of the vinyl group during exposure.

We proposed that the increase in base solubility of positive-tone resists containing the styrenecarboxylate ligand occurs in two steps. The first step is free-radical polymerization of the terminal olefin resulting in a polymeric network. The second step is the breaking of the antimony oxygen bond and subsequent formation of a carboxylic acid. This results in a polymeric network containing carboxylic acids and antimony carboxylates. We suspect the ratio of carboxylic acid groups to antimony carboxylates increases with exposure to EUV rendering the polymeric network increasingly soluble in an alkaline developer. More evidence needs to be gathered to support this hypothesis including identification of intermediates and functional groups in the exposed film.

### EXAMPLES

### Experimental Methods and Resist Formulation and Spin Coating

Outgassing Analysis: Resist formulations were prepared by dissolving solids at 2 wt % in 1,4-dioxane and filtering through 0.45 μm PTFE filters. Formulations were spin cast onto 4-inch virgin silicon wafers at 2000 RPM for 60 seconds. Wafers were subject to a post application bake at 60° C. for 60 seconds.

EUV Lithography: Resist formulations were prepared by dissolving solids at 2 wt % in an appropriate solvent and filtering through 0.45 μm PTFE filters. Formulations were then spin cast onto 4-inch virgin silicon wafers at 1500 RPM for 60 seconds. Some wafers were pretreated with a custom underlayer (crosslinked hydroxyethyl methacrylate/methyl methacrylate copolymers) to promote adhesion. Wafers were subject to a post application bake at 60° C. for 60 seconds unless otherwise specified. No post-exposure bakes were performed. Resist films were 50 to 100 nm thick as measured by ellipsometry. Conditions for each resist can be found below in Table 1.

TABLE 1
Spin coating conditions for resists exposed
to EUV at PSI for contrast curves.

| Resist | Substrate | Cast Solvent |
|---|---|---|
| SH-11 | Si | 1-methoxy-2-propanol |
| NU-111 | Si | 1,4-dioxane |
| JG-11 | Si | 1,2-dichloroethane |
| JP-30 | Si | 1,4-dioxane |
| NU-136 | Underlayer | 1-methoxy-2-propanol |
| NU-126 | Underlayer | ethyl lactate |
| NU-127 | Underlayer | PGMEA |
| NU-129 | Underlayer | 1,4-dioxane |
| SH-10 | Si | ethyl lactate |
| MM-18 | Underlayer | 1,4-dioxane |
| NU-135 | Underlayer | 1,4-dioxane |
| MM-10 | Underlayer | 1,4-dioxane |
| NU-123 | Si | 1-methoxy-2-propanol |

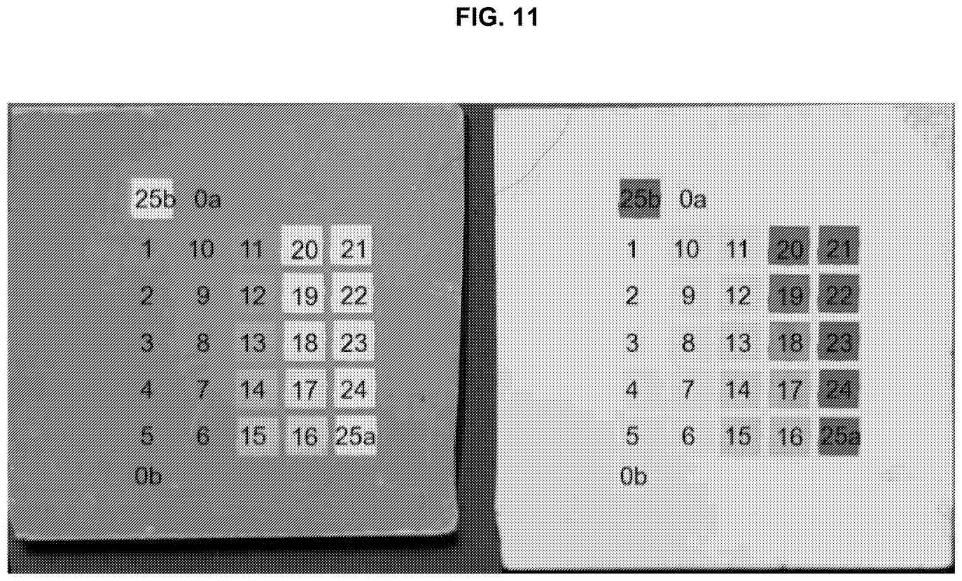

EUV exposures were performed at the Paul Scherrer Institute (PSI) XIL-II beamline. Resists were exposed through an open frame, to make contrast curves. Each resist received 26 exposures including an index dose (a replication of the highest dose on the curve) for reference (FIG. 11). Specified experiments used an older method for calibrating dose and can be converted using a factor of approximately 1.8.

Contrast Curve Analysis: Resist film thicknesses were measured using a J. A. Woollam M-2000 fixed angle ellipsometer equipped with Complete Ease software. Thicknesses were fitted using a Cauchy model for the photoresist and a Cauchy model for the underlayer where appropriate. Thickness was plotted relative to an unexposed portion of the resist from the same wafer that was not subject to vacuum conditions of the EUV exposure chamber. The thickness of the replicate highest dose spots were averaged to give the value in each plot. In addition to the 26 exposure spots, film thickness was measured at two unexposed locations on the same section wafer that was exposed (FIG. 11). These two thickness measurements were averaged to give the zero-dose thickness. The averaged zero-dose points were plotted on the y-axis of contrast curves to show the relative thickness of unexposed resist. This was done to illustrate dark loss as well as any solubility change between unexposed resist and the lowest exposure dose.

General: All reagents and solvents were purchased through either Sigma Aldrich or Alpha Aesar and used as received. All glassware was dried in an oven overnight prior to use. Reactions were carried out under a nitrogen atmosphere.

Synthesis: The desired R₃Sb(O₂CR′)₂ compounds were synthesized via triorganoantimony diiodide intermediates. Ligand exchange was then performed to substitute iodides for the desired carboxylate. Synthesis of tri(isopropenyl)antimony (p-vinylbenzoate)₂ (SH-11) is shown below to exemplify this process.

Synthesis of tri(isopropenyl)antimony diiodide: A 250 mL round-bottom flask was purged for 15 minutes under a stream of nitrogen before the addition of 48.4 mL of a 0.5 M isopropenylmagnesium bromide solution in THF (24.2 mmol). The grignard solution was cooled to −15° C. Antimony(Ill) bromide (2.5 g, 6.9 mmol) was then solubilized in 10 mL diethyl ether and added dropwise to the grignard solution via syringe across one hour. The reaction was allowed to gradually warm to room temperature and stirred for three hours before quenching with dropwise addition of 5 mL saturated ammonium chloride via syringe. To the reaction mixture, 30 mL of dichloromethane and 15 mL of deionized water were added to solubilize any solids. The organic phase was transferred and filtered via cannula. tri(isopropenyl)antimony(II) was then oxidized to tri(isopropenyl)antimony(V) diiodide by the addition of iodine (3.4 g, 6.9 mmol) dissolved in 20 ml of tetrahydrofuran. Addition was ceased when the solution began to change color. Rotary evaporation to dryness yielded tri(isopropenyl) diiodide. Crude product was recrystallized from diethyl ether yielding 2.714 g (79%) clear rectangular crystals (decomposes: 153-164° C., no melting). ¹H-NMR (500 MHz, Chloroform-d) δ 5.80 (s, 1H), 5.68 (s, 1H), 2.46 (s, 3H).

Synthesis of tri(isopropenyl)antimony (p-vinylbenzoate)₂ tri(isopropenyl)antimony diiodide: (1 g, 2 mmol) was dissolved in 10 mL of dichloromethane in a 50 mL round-bottom flask. A suspension of potassium styrenecarboxylate (1.122 g, 3 mmol) in 5 mL deionized water was added before equipping a reflux condenser. The biphasic mixture was then held at 50° C. with vigorous stirring for three hours. After cooling to room temperature, the organic phase was collected and washed twice with deionized water followed by one washing with brine. The organic phase was then dried over magnesium sulfate before filtering through cotton. Rotary evaporation yielded an oily liquid which crystallized spontaneously into 1.012 g (94% yield) flat needles (decomposes: 103° C., no melting). ¹H-NMR (500 MHz, Chloroform-d) δ 7.96 (d, J=8.2 Hz, 4H), 7.43 (d, J=8.2 Hz, 4H), 6.75 (dd, 2H), 5.81-5.86 (m, 5H), 5.75 (d, 3H), 5.34 (d, 2H), 2.41 (s, 9H).

Tri(isopropenyl)antimony (p-vinylbenzoate)₂ (SH-11): Obtained 1.012 g (94% yield) flat needles (decomposes: 103° C., no melting). ¹H-NMR (500 MHz, Chloroform-d) δ 7.96 (d, J=8.2 Hz, 4H), 7.43 (d, J=8.2 Hz, 4H), 6.75 (dd, 2H), 5.81-5.86 (m, 5H), 5.75 (d, 3H), 5.34 (d, 2H), 2.41 (s, 9H).

Tri(propenyl)antimony (p-vinylbenzoate)₂ (JG-11): Obtained 127 mg (74% yield) white crystalline needles.

Tri(isopropyl)antimony (p-vinylbenzoate)₂ (NU-111): Obtained ¹H-NMR (500 MHz, Chloroform-d) δ 8.01 (d, J=8 Hz, 4H), 7.46 (d, J=8 Hz, 4H), 6.76 (dd, J=18, 11 Hz, 2H), 5.84 (d, J=18 Hz, 2H), 5.35 (d, J=11 Hz, 2H), 3.35 (sep, J=7 Hz, 3H), 1.68 (d, J=7 Hz, 18H).

Tri(methyl)antimony (p-vinylbenzoate)₂ (JG-229): Obtained 462 mg (32% yield) white powder (decomposes: 91.7° C., no melting).

Tri(phenyl)antimony (p-vinylbenzoate)₂ (JP-30)³: Obtained 0.1 H NMR (400 MHz, Chloroform-d) δ 8.14 to 8.04 (m, 6H), 7.86 (d, J=8.2 Hz, 4H), 7.51 to 7.40 (m, 9H), 7.33 (d, J=8.1 Hz, 4H), 6.67 (dd, J=17.6, 10.9 Hz, 2H), 5.75 (d, J=17.6 Hz, 2H), 5.26 (d, 2H).

Tri(cyclohexyl)antimony (p-vinylbenzoate)₂ (JG-238): Obtained 545 (72% yield) white fibrous crystals (decomposes: 99.4° C., no melting). ¹H-NMR (500 MHz, CHLOROFORM-D) δ 8.03 (d, J=8.2 Hz, 4H), 7.48 (d, J=8.2 Hz, 4H), 6.78 (dd, J=17.5, 10.8 Hz, 2H), 5.85 (d, J=17.5 Hz, 2H), 5.35 (d, J=11.0 Hz, 2H), 3.31 (tt, J=12.5, 3.0 Hz, 3H), 2.35-2.15 (m, 6H), 2.15-1.99 (m, 6H), 1.84-1.72 (m, 6H), 1.70-1.59 (m, 3H), 1.45-1.26 (m, 9H).

The entire disclosure of all applications, patents, and publications cited herein are herein incorporate by reference in their entirety. While the foregoing is directed to embodiments of the present disclosure, other and further embodiments of the disclosure may be devised without departing from the basic scope thereof.

The present invention is not to be limited by the above description, but to be defined by the appended claims and their equivalents.

### REFERENCES

Ito, H. Chemical Amplification Resists for Microlithography. In Microlithography—Molecular/mprinting; Advances in Polymer Science; Springer Berlin Heidelberg: Berlin, Heidelberg, 2005; Vol. 172, pp 37-245. doi.org/10.1007/b97574; Tsuchimura, T. Recent Progress in Photo-Acid Generators for Advanced Photopolymer Materials. J. Photopolym. Sci. Technol. 2020, 33 (1), 15-26. doi.org/10.2494/photopolymer.33.15; Jakatdar, N. H.; Niu, X.; Spanos, C. J.; Romano, A. R.; Bendik, J. J.; Kovacs, R. P.; Hill, S. L. Characterization of a Positive Chemically Amplified Photoresist for Process Control; Singh, B., Ed.; Santa Clara, CA, U.S., 1998; p 586. doi.org/10.1117/12.30877; Polymers in Electronics; Davidson, T., Ed.; ACS Symposium Series; American Chemical Society: Washington, D.C., 1984; Vol. 242. doi.org/10.1021/bk-1984-0242; Gallatin, G. M. Resist Blur and Line Edge Roughness. In Optical Microlithography XVIII; SPIE: San Jose, United States, 2005; p 4. doi.org/10.1117/12.607233; Goldfarb, D. L.; Bruce, R. L.; Bucchignano, J. J.; Klaus, D. P.; Guillorn, M. A.; Wu, C. J. Pattern Collapse Mitigation Strategies for EUV Lithography; Naulleau, P. P., Wood II, O. R., Eds.; San Jose, California, 2012; p 832205. doi.org/10.1117/12.915431; Thackeray, J. W. Stochastic Exposure Kinetics of Extreme Ultraviolet Photoresists: Simulation Study. J. MicroNanolithography MEMS MOEMS 2011, 10 (3), 033019 doi.org/10.1117/1.3631753; Gronheid, R.; Fonseca, C.; Leeson, M. J.; Adams, J. R.; Strahan, J. R.; Willson, C. G.; Smith, B. W. EUV Resist Requirements: Absorbance and Acid Yield; Henderson, C. L., Ed.; San Jose, California, USA, 2009; p 727332. doi.org/10.1117/12.814716; Xu, H.; Kosma, V.; Giannelis, E.; Ober, C. K.; Sakai, K. EUV Photolithography: Resist Progress and Challenges. In Extreme Ultraviolet (EUV) Lithography IX; Felix, N. M., Goldberg, K. A., Eds.; SPIE: San Jose, United States, 2018; p 2. doi.org/10.1117/12.2302759; Stowers, J. K.; Telecky, A.; Kocsis, M.; Clark, B. L.; Keszler, D. A.; Grenville, A.; Anderson, C. N.; Naulleau, P. P. Directly Patterned Inorganic Hardmask for EUV Lithography. In Extreme Ultraviolet (EUV) Lithography II; SPIE, 2011; Vol. 7969, pp 386-396. doi.org/10.1117/12.879542.; Krysak, M.; Trikeriotis, M.; Schwartz, E.; Lafferty, N.; Xie, P.; Smith, B.; Zimmerman, P.; Montgomery, W.; Giannelis, E.; Ober, C. K. Development of an Inorganic Nanoparticle Photoresist for EUV, e-Beam, and 193 nm Lithography; Allen, R. D., Somervell, M. H., Eds.; San Jose, California, USA, 2011; p 79721C. doi.org/10.1117/12.879385; Passarelli, J.; Murphy, M.; Re, R. D.; Sortland, M.; Hotalen, J.; Dousharm, L.; Fallica, R.; Ekinci, Y.; Neisser, M.; Freedman, D. A.; Brainard, R. L. Organometallic Carboxylate Resists for Extreme Ultraviolet with High Sensitivity. J. MicroNanolithography MEMS MOEMS 2015, 14 (4), 043503. doi.org/10.1117/1.JMM.14.4.043503; Passarelli, J.; Sortland, M.; Re, R. D.; Cardineau, B.; Sarma, C.; Freedman, D. A.; Brainard, R. L. Bismuth Resists for EUV Lithography. J. Photopolym. Sci. Technol. 2014, 27 (5), 655-661; doi.org/10.2494/photopolymer.27.655; Wilklow-Marnell, M.; Moglia, D.; Steimle, B. First-Row Transitional-Metal Oxalate Resists for EUV. J. MicroNanolithography MEMS MOEMS 2018, 17 (04), 1. doi.org/10.1117/1.JMM.17.4.043507; Sortland, M.; Del Re, R.; Passarelli, J.; Hotalen, J.; Vockenhuber, M.; Ekinci, Y.; Neisser, M.; Freedman, D.; Brainard, R. L. Positive-Tone EUV Resists: Complexes of Platinum and Palladium; Wood, O. R., Panning, E. M., Eds.; San Jose, California, United States, 2015; p 942227. doi.org/10.1117/12.2086598; Del Re, R.; Sortland, M.; Pasarelli, J.; Cardineau, B.; Ekinci, Y.; Vockenhuber, M.; Neisser, M.; Freedman, D.; Brainard, R. L. Low-LER Tin Carboxylate Photoresists Using EUV; Wood, O. R., Panning, E. M., Eds.; San Jose, California, United States, 2015; p 942221. doi.org/10.1117/12.2086597; Brunner, T. A.; Fonseca, C. A. Optimum Tone for Various Feature Types: Positive versus Negative; Houlihan, F. M., Ed.; Santa Clara, CA, 2001; p 30. doi.org/10.1117/12.436866; Hotalen, J.; Murphy, M.; Earley, W.; Vockenhuber, M.; Ekinci, Y.; Freedman, D. A.; Brainard, R. L. Advanced Development Techniques for Metal-Based EUV Resists; Panning, E. M., Goldberg, K. A., Eds.; San Jose, California, United States, 2017; p 1014309. doi.org/10.1117/12.2258126; Michael T. Murphy. Mechanistic Investigation of Antimony Carboxylate Photoresists for EUV Lithography. PhD, University at Albany CNSE, 2019; Ryan Del Re. Molecular Organometallic Resists of Tin and Tellurium, University at Albany CNSE, 2015; Logarithmic scales do not contain the number zero. This point was included as the relative thickness of unexposed resist is vital in understanding the contrast curve for the resist. This point provides insight into the solubility of the resist with no exposure to EUV; Murphy, M.; Narasimhan, A.; Grzeskowiak, S.; Sitterly, J.; Schuler, P.; Richards, J.; Denbeaux, G.; Brainard, R. L. Antimony Photoresists for EUV Lithography: Mechanistic Studies; Panning, E. M., Goldberg, K. A., Eds.; San Jose, California, United States, 2017; p 1014307. doi.org/10.1117/12.2258119; Otsuka, T.; Muroya, Y.; Ikeda, T.; Komuro, Y.; Kawana, D.; Kozawa, T. Decarboxylation Efficiency of Carboxylic Acids as Ligands of Metal Oxide Nanocluster Resists upon γ-Ray Irradiation. Jpn. J. Appl. Phys. 2022, 61 (3), 036503. doi.org/10.35848/1347-4065/ac4b43; Narasimhan, A.; Wisehart, L.; Grzeskowiak, S.; Ocola, L. E.; Denbeaux, G.; Brainard, R. L. What We Don't Know About EUV Exposure Mechanisms. J. Photopolym. Sci. Technol. 2017, 30 (1), 113-120. doi.org/10.2494/photopolymer.30.113; Torok, J.; Re, R. D.; Herbol, H.; Das, S.; Bocharova, I.; Paolucci, A.; Ocola, L. E.; Ventrice Jr., C.; Lifshin, E.; Denbeaux, G.; Brainard, R. L. Secondary Electrons in EUV Lithography. J. Photopolym. Sci. Technol. 2013, 26 (5), 625-634. doi.org/10.2494/photopolymer.26.625; Theofanis, P.; Blackwell, J. M.; Krysak, M. E.; Gstrein, F. Modeling Photon, Electron, and Chemical Interactions in a Model Hafnium Oxide Nanocluster EUV Photoresist. In Extreme Ultraviolet (EUV) Lithography XI; Felix, N. M., Lio, A., Eds.; SPIE: San Jose, United States, 2020; p 14. doi.org/10.1117/12.2552837; Thakur, N.; Giuliani, A.; Nahon, L.; Castellanos, S. Photon-Induced Fragmentation of Zinc-Based Oxoclusters for EUV Lithography Applications. J. Photopolym. Sci. Technol. 2020, 33 (2), 153-158. doi.org/10.2494/photopolymer.33.153; Wu, L.; Liu, J.; Vockenhuber, M.; Ekinci, Y.; Castellanos, S. Hybrid EUV Resists with Mixed Organic Shells: A Simple Preparation Method: Hybrid EUV Resists with Mixed Organic Shells: A Simple Preparation Method. Eur. J. Inorg. Chem. 2019, 2019 (38), 4136-4141. doi.org/10.1002/ejic.201900745; Pollentier, I.; Vesters, Y.; Jiang, J.; Vanelderen, P.; De Simone, D. Unraveling the Role of Secondary Electrons upon Their Interaction with Photoresist during EUV Exposure. In International Conference on Extreme Ultraviolet Lithography 2017; Gargini, P. A., Ronse, K. G., Naulleau, P. P., Itani, T., Eds.; SPIE: Monterey, United States, 2017; p 17. doi.org/10.1117/12.2281449; Fukuda, H. Localized and Cascading Secondary Electron Generation as Causes of Stochastic Defects in Extreme Ultraviolet Projection Lithography. J. MicroNanolithography MEMS MOEMS 2019, 18 (01), 1. doi.org/10.1117/1.JMM.18.1.013503; Narasimhan, A.; Grzeskowiak, S.; Ackerman, C.; Flynn, T.; Denbeaux, G.; Brainard, R. L. Mechanisms of EUV Exposure: Electrons and Holes; Panning, E. M., Goldberg, K. A., Eds.; San Jose, California, United States, 2017; p 101430 W. doi.org/10.1117/12.2258321.Hasan, S.; Murphy, M.; Weires, M.; Grzeskowiak, S.; Denbeaux, G.; and Brainard, R. L. Oligomers of MORE: Molecular Organometallic Resists for EUV. In Advances in Patterning Materials and Processes XXXVI; Gronheid, R., Sanders, D. P., Eds.; SPIE: San Jose, United States, 2019; p 61.doi.org/10.1117/12.2516010

What is claimed is:

1. A positive-tone lithographic composition comprising the following formula, 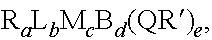
wherein: M is tellurium (Te), antimony (Sb), tin (Sn), Iodine (I) or bismuth (Bi);
R, when present, is independently an aromatic or aliphatic hydrocarbon;
L, when present, is independently a ligand comprising a heteroatom bound to M;
B, when present, is a molecular fragment that is bound to two or more M atoms;
Q is a molecular fragment comprising a heteroatom bound to M and a carbon, sulfur or phosphorus bound to a R′ group;
R′ is an alkyl or aromatic fragment containing either an alkene or an alkyne;
and, wherein a=0-12; b=0-12; c=1-12; d=0-12; and e=1-8.

2. The positive-tone lithographic composition of claim 1, wherein R is independently an aromatic or aliphatic hydrocarbon selected from the group consisting of: —C₆H₅, —CH₃, —CH₂CH₃, —CH(CH₃)₂, —C(CH₃)₃, —CH═CH₂, —C(CH₃)=CH₂, —CH₂CH═CH₂, —CH₂C° CH, —CH₂C° N, —CH₂C₆H₅, —C₆H₄CH═CH₂, —C₆H₄C(CH₃)=CH₂, —CH₂C₆H₄CH═CH₂, —C₆H₄OCH₃, p-C₆H₄OCH₃, —C₆H₄CH₂CH₃, —CH₂C₆H₄OCH₃, —C₆H₁₁, —CH₂C₁₀H₇, —CH₂C₆H₄C₆H₅, —CH(C₆H₅)₂, —CH₂C₆H₄C(CH₃)₃, —CH₂C₆H₄F, —CH₂C₆H₃F₂, —CH₂C₆H₂F₃, —CH₂C₆F₅, —CH(CH₃)C₆H₅, —CH(CH₃)C₁₀H₇, —CH(CH₃)C₆H₄C₆H₅, and —CH(CH₃)C₆H₄C(CH₃)₃.

3. The positive-tone lithographic composition of claim 1, wherein L is independently a ligand selected from the group consisting of: —F, —Cl, —Br, —I, —OH₂, —OH, —OCH₃, —OCH(CH₃)₂, —OC(CH₃)₃, —NC₅H₅, —O(CH₂CH₃)₂, —P(CH₂CH₃)₃, —O(CH₂)₄, —SH₂, —SH, —SCH₃, —SCH(CH₃)₂, —SC(CH₃)₃, —S(CH₂CH₃)₂, —S(CH₂)₄, —CN, —O₂CR, or —C₂O₄.

4. The positive-tone lithographic composition of claim 1, wherein B is selected from the group consisting of: —O—, —S—, —Te(O)₆—, —I(=O)O₅—, —C₂O₄—, —SO₄—, —PO₄—, —(CH₂)₂C₆H₄(CH₂)₂—, —OO—, —OCH₂O—, —OCH₂CH₂O—, —OCH₂CH₂CH₂O—, —OCH₂CH₂CH₂CH₂O—, —OC₆H₄O—, —OCH₂C₆H₄CH₂O—, —OCH₂CH═CHCH₂O—, —OCH₂C≡CCH₂O—, —SCH₂CH₂S—, —SCH₂CH₂CH₂S—, —SCH₂CH₂CH₂CH₂S—, —SC₆H₄S—, —SCH₂C₆H₄CH₂S—, —SCH₂CH═CHCH₂S—, —SCH₂C≡CCH₂S—, —O₂CCH₂CO₂—, —O₂CCH₂CH₂CO₂—, —O₂CCH₂C₆H₄CH₂CO₂—, —NHC═ONH—, —CH₂—, —CH(C₆H₅)—, —CH(CN)—, —CH₂CH₂—, —CH₂CH₂CH₂—, —CH₂CH₂CH₂CH₂—, —CH(CH₃)—, —CH(C₆H₅)—, —CH₂CH═CHCH₂—, —CH₂C° CCH₂—, and —CH₂C₆H₄CH₂.

5. The positive-tone lithographic composition of claim 1, wherein Q is selected from the group consisting of: —O₂C—, —O₃S—, —O₃P—, —O₂(HO)P—, —S(O═)C—, and —O₂C(O=C)—.

6. The positive-tone lithographic composition of claim 1, wherein QR′ is selected from the group consisting of:

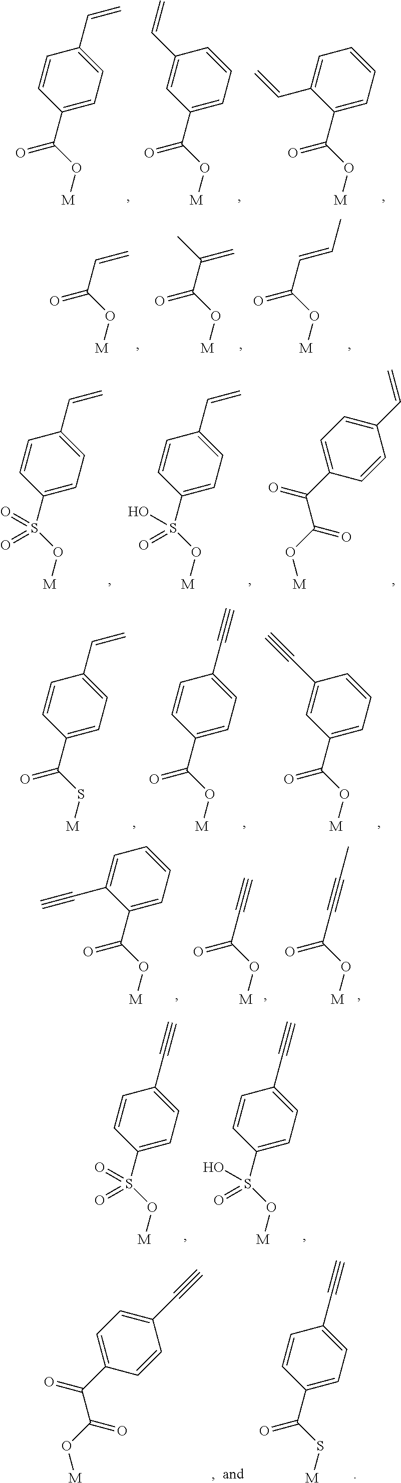

7. The positive-tone lithographic composition of claim 1, wherein QR′ is (p-vinylbenzoate)₂ and M is Sb.

8. The positive-tone lithographic composition of claim 1, wherein said compound comprises one of the following structural formula:

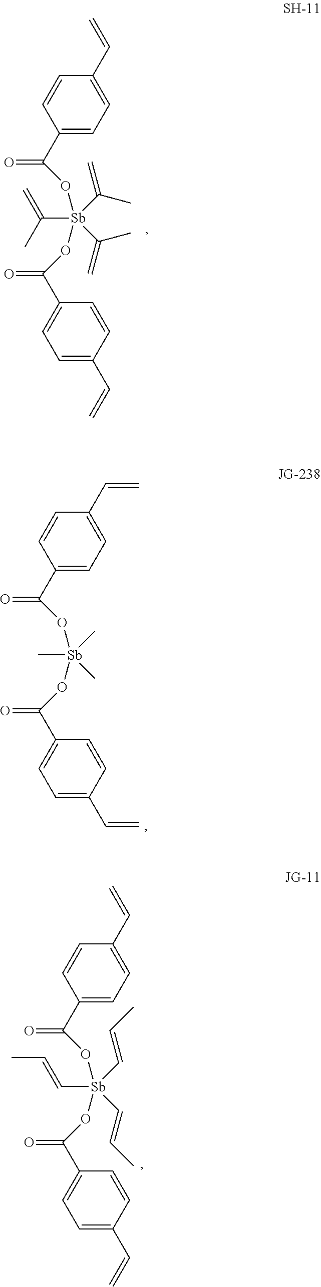

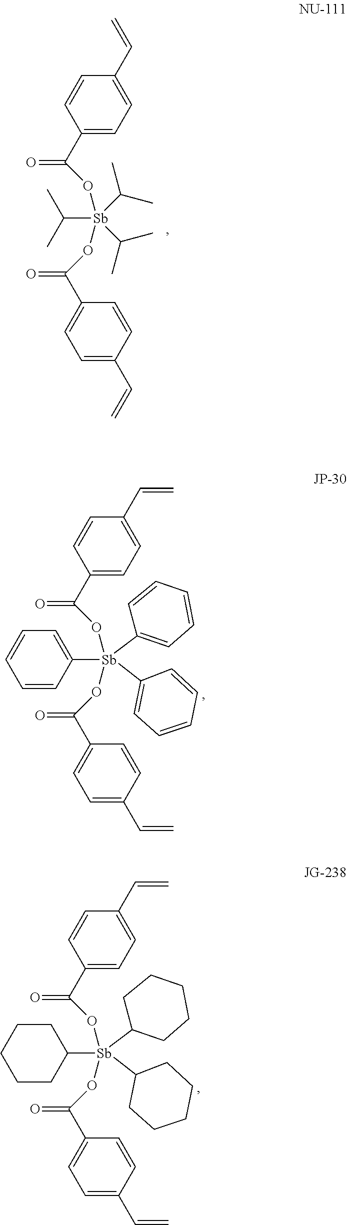

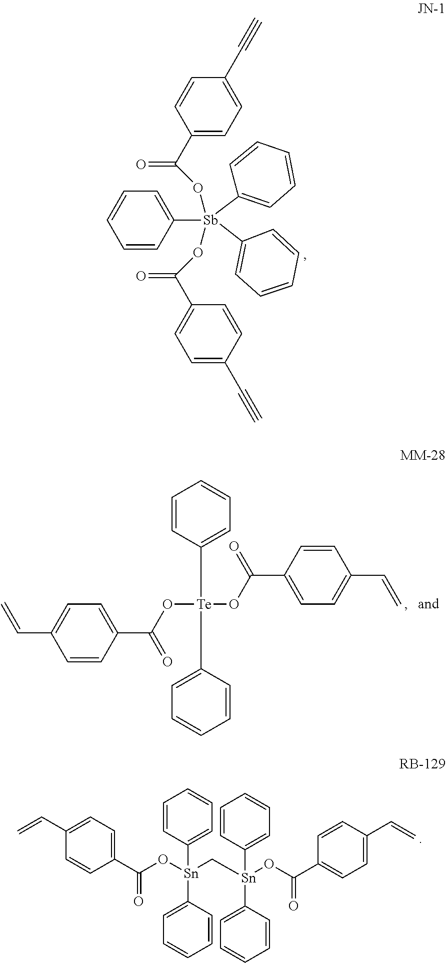

9. The positive-tone lithographic composition of claim 1, wherein said positive-tone lithographic composition has following structural formula:

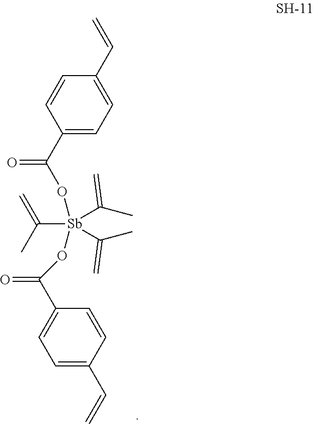

10. The positive-tone lithographic composition of claim 1, wherein said positive-tone lithographic composition has following structural formula:

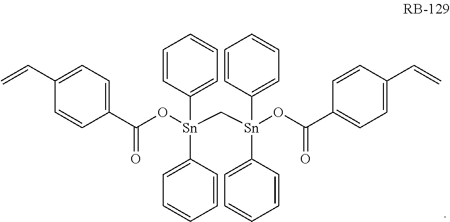 [SMILES: C=Cc1ccc(C(=O)[O][Sn]([CH2][Sn]([O]C(=O)c2ccc(C=C)cc2)([c]2ccccc2)[c]2ccccc2)([c]2ccccc2)[c]2ccccc2)cc1]

11. The positive-tone lithographic composition of claim 1, wherein the composition's solubility increases in an alkaline aqueous developer solution upon exposure to actinic radiation to provide positive-tone properties.

12. The positive-tone lithographic composition of claim 11, wherein the developer is 0.1-20% of an aqueous 0.26 M solution of tetramethylammonium hydroxide (TMAH).

13. The positive-tone lithographic composition of claim 11, wherein the developer is 1-10% of an aqueous 0.26 M of tetramethylammonium hydroxide (TMAH) solution.

14. A coating solution comprising, an organic solvent and a the positive-tone lithographic composition of claim 1.

15. A method for forming a radiation patternable coating, the method comprising: contacting the coating solution of claim 14, with a substrate under conditions suitable for forming a film atop the substrate.
